(19) United States
(12) Patent Application Publication
(10) Pub. No.: US 2015/0122316 A1
(43) Pub. Date: May 7, 2015

(54) PHOTOVOLTAIC CELLS INCLUDING HALIDE MATERIALS

(71) Applicant: OMNIPV, INC., Menlo Park, CA (US)

(72) Inventors: John Kenney, Palo Alto, CA (US); Jian Jim Wang, Orefield, PA (US); John Midgley, San Carlos, CA (US)

(21) Appl. No.: 14/515,420

(22) Filed: Oct. 15, 2014

Related U.S. Application Data
(60) Provisional application No. 61/891,762, filed on Oct. 16, 2013.

(51) Int. Cl. H01L 31/0725; H01L 31/0224; H01G 9/20; H01L 31/048

(52) U.S. Cl. CPC H01L 31/0725; H01L 31/048; H01L 31/022433; H01G 9/2059
USPC 136/255; 136/259; 136/256

(57) ABSTRACT

A photovoltaic cell includes: (1) a front contact; (2) a back contact; (3) a set of stacked layers between the front contact and the back contact; and (4) an encapsulation layer covering side surfaces of the set of stacked layers. At least one of the set of stacked layers includes a halide material having the formula: [AₐB_{b}XₓX′_{x′}X″_{x″}X′″_{x′″}][dopants], where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

### CROSS REFERENCE TO RELATED APPLICATION

This application claims the benefit of U.S. Provisional Application No. 61/891,762, filed on Oct. 16, 2013, the content of which is incorporated herein by reference in its entirety.

### TECHNICAL FIELD

The disclosure relates generally to photovoltaic (“PV”) cells. More particularly, the disclosure relates to PV cells including halide materials.

### BACKGROUND

Various PV technologies have been proposed for large-scale solar energy conversion. The wafer-based first generation PV cells have been followed by thin-film semiconductor absorber layers and nanostructured (or mesostructured) PV cells that rely on a distributed heterojunction to generate charge and transport positive and negative charges in spatially separated phases. Although various materials have been used in PV cells, the goal of attaining high-efficiency, thin-film PV cells has yet to be achieved.

It is against this background that a need arose to develop the PV cells described herein.

### SUMMARY

In some embodiments, a photovoltaic cell includes: (1) a front contact; (2) a back contact; (3) a set of stacked layers between the front contact and the back contact; and (4) an encapsulation layer covering side surfaces of the set of stacked layers. At least one of the set of stacked layers includes a halide material having the formula:

[AₐB_{b}XₓX′_{x′}X″_{x″}X′″_{x′″}][dopants],

where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

In some embodiments, a photovoltaic cell includes: (1) a top substrate; (2) a bottom substrate; (3) a set of stacked layers between the top substrate and the bottom substrate; and (4) a sealing structure extending between the top substrate and the bottom substrate and surrounding side surfaces of the set of stacked layers. At least one of the set of stacked layers includes a halide material having the formula:

[AₐB_{b}XₓX′_{x′}X″_{x″}X′″_{x′″}][dopants],

where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

In some embodiments, a photovoltaic cell includes: (1) a top conductive layer; (2) a bottom conductive layer; and (3) a set of stacked layers between the top conductive layer and the bottom conductive layer and including a pair of photoactive layers. The top conductive layer covers a top surface and side surfaces of the set of stacked layers, and at least one of the pair of photoactive layers includes a halide material having the formula:

[AₐB_{b}XₓX′_{x′}X″_{x″}X′″_{x′″}][dopants],

where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

In some embodiments, a photovoltaic cell includes: (1) a top conductive layer; (2) a bottom conductive layer; and (3) a set of stacked layers between the top conductive layer and the bottom conductive layer and including a top photoactive layer and a bottom photoactive layer. The top photoactive layer covers a top surface and side surfaces of the bottom photoactive layer, and the bottom photoactive layer includes a halide material having the formula:

[AₐB_{b}XₓX′ₓX″_{x″}X′″_{x′″}][dopants],

where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

In some embodiments, a multijunction photovoltaic cell includes: (1) a front contact; (2) a back contact; and (3) a set of stacked layers between the front contact and the back contact and including: (a) a first pair of photoactive layers corresponding to a first cell having a first bandgap energy; and (b) a second pair of photoactive layers corresponding to a second cell that is disposed between the first cell and the back contact and having a second bandgap energy that is smaller than the first bandgap energy. At least one of the set of stacked layers includes a halide material having the formula:

[AₐB_{b}XₓX′ₓX″_{x″}X′″_{x′″}][dopants],

where A is selected from elements of Group 1 and organic moieties, B is selected from elements of Group 14, X, X′, X″, and X′″ are independently selected from elements of Group 17, a is in the range of 1 to 12, b is in the range of 1 to 8, and a sum of x, x′, x″, and x′″ is in the range of 1 to 12.

Other aspects and embodiments of the disclosure are also contemplated. The foregoing summary and the following detailed description are not meant to restrict the disclosure to any particular embodiment but are merely meant to describe some embodiments of the disclosure.

### BRIEF DESCRIPTION OF THE DRAWINGS

For a better understanding of the nature and objects of some embodiments of the disclosure, reference should be made to the following detailed description taken in conjunction with the accompanying drawings.

FIG. 1 illustrates a dye-sensitized PV cell implemented in accordance with an embodiment of the disclosure.

FIG. 2 illustrates a dye-sensitized PV cell implemented in accordance with another embodiment of the disclosure.

FIG. 3 illustrates a thin-film heterojunction PV cell implemented in accordance with another embodiment of the disclosure.

FIG. 4 illustrates a thin-film heterojunction PV cell implemented in accordance with another embodiment of the disclosure.

FIG. 5 illustrates a thin-film heterojunction PV cell implemented in accordance with another embodiment of the disclosure.

FIG. 6 illustrates a thin-film heterojunction PV cell implemented in accordance with another embodiment of the disclosure.

FIG. 7 illustrates the theoretical efficiency for a two junction device with absorber layers of varying bandgap energies, according to another embodiment of the disclosure.

FIG. 8 illustrates a multijunction PV cell implemented in accordance with another embodiment of the disclosure.

FIG. 9 illustrates emission spectra of three direct bandgap halide materials, namely CsSnI₃ (about 1.3 eV), CsSnBr₃ (about 1.7 eV), and CsSnCl₃ (about 2.4 eV), according to an embodiment of the disclosure.

FIGS. 10(a), 10(b), 10(c), and 10(d) illustrate emission and absorption spectra of halide materials formed with varying stoichiometric ratios of reactants, according to an embodiment of the disclosure.

FIGS. 11(a), 11(b), 11(c), and (d) illustrate emission and absorption spectra of halide materials formed with varying stoichiometric ratios of reactants, according to an embodiment of the disclosure.

FIGS. 12(a), 12(b), and 12(c) illustrate emission and absorption spectra of halide materials formed with varying stoichiometric ratios of reactants (CsI+SnCl₂=3:2, 2:3, 5:2), according to an embodiment of the disclosure.

FIG. 13 illustrates optical spectra obtained for a thin film of a halide material, according to an embodiment of the disclosure.

FIG. 14 illustrates emission, excitation, and absorption spectra of a black halide material (CsSnBr₃), according to an embodiment of the disclosure.

FIG. 15 illustrates X-ray diffraction and absorption spectra of a yellow halide material (Cs₂SnICl₃), according to an embodiment of the disclosure.

FIG. 16 illustrates X-ray diffraction and absorption spectra of SnO, and an emission spectrum of a halide material formed by reacting SnO and CsI at about 1100° C., according to an embodiment of the disclosure.

FIG. 17 illustrates absorption spectra of Cs₂SnCl₂I₂ (yellow), CsSnBr₂I (black), Cs₂SnBr₂I₂ (black), and Cs₂SnI₃Cl, according to an embodiment of the disclosure.

### DETAILED DESCRIPTION

### Halide Materials

Embodiments of the disclosure relate to halide materials having desirable characteristics for use in PV cells. Advantageously, the halide materials can be non-toxic, and can be inexpensively formed from low-cost and abundant reactants. The halide materials can be included in PV cells to yield high solar energy conversion efficiencies.

Desirable halide materials include a class of materials that can be represented with reference to the formula:

[AₐB_{b}XₓX′_{x′}X″_{x″}X′″_{x′″}][dopants] (1)

In formula (1), A is selected from elements of Group 1, such as sodium (e.g., as Na(I) or Na⁺¹), potassium (e.g., as K(I) or K⁺¹), rubidium (e.g., as Rb(I) or Rb⁺¹), and cesium (e.g., as Cs(I) or Cs⁺¹) and organic moieties, such as monovalent organic cations and polyvalent (e.g., divalent) organic cations; B is selected from elements of Group 14, such as germanium (e.g., as Ge(II) or Ge⁺² or as Ge(IV) or Ge⁺⁴), tin (e.g., as Sn(II) or Sn⁺² or as Sn(IV) or Sn⁺⁴), and lead (e.g., as Pb(II) or Pb⁺² or as Pb(IV) or Pb⁺⁴); and X, X′, X″, and X′″ are independently selected from elements of Group 17, such as fluorine (e.g., as F⁻¹), chlorine (e.g., as Cl⁻¹), bromine (e.g., as Br⁻¹), and iodine (e.g., as I⁻¹).

Referring to formula (1), a is an integer (or non-integer) that can be in the range of 1 to 12, such as from 1 to 9, from 1 to 5, or from 1 to 4; b is an integer (or non-integer) that can be in the range of 1 to 8, such as from 1 to 5, from 1 to 3, or from 1 to 2; and the sum of x, x′, x″, and x′″ is an integer (or non-integer) that can be in the range of 1 to 12, such as from 3 to 12, from 3 to 9, or from 3 to 6. In some instances, the sum of x, x′, x″, and x′″ can be substantially equal to a+2b, such as for purposes of charge balance when oxidation states of A, B, and each of X, X′, X″, and X′″ are +1, +2, and −1, respectively. For example, a can be equal to 1, and the sum of x, x′, x″, and x′″ can be substantially equal to 1+2b. As another example, X can be iodine, and formula (1) can represented as [AₐB_{b}I_{(a+2b)-x′-x″-x′″}F_{x′}Cl_{x″}Br_{x′″}][dopants], where each of x′, x″, and x′″ can be zero or greater than zero. In other instances, the sum of x, x′, x″, and x′″ can be substantially equal to 2a+2b, such as for purposes of charge balance when oxidation states of A, B, and each of X, X′, X″, and X′″ are +2, +2, and −1, respectively. For example, a can be equal to 1, and the sum of x, x′, x″, and x′″ can be substantially equal to 2+2b. As another example, X can be iodine, and formula (1) can represented as [AₐB_{b}I_{(2a+2b)-x′-x″-x′″}F_{x′}Cl_{x″}Br_{x′″}][dopants], where each of x′, x″, and x′″ can be zero or greater than zero. It is contemplated that one or more of a, b, x, x′, x″, and x′″ can have fractional values within their respective ranges. It is also contemplated that a halide material represented by formula (1) can be substantially devoid of iodine to attain a higher bandgap energy (e.g., for use in emitter layers or upper layers in multijunction PV cells), such as where X, X′, X″, and X′″ are independently selected from elements of Group 17 except iodine. A higher bandgap energy also can be attained by having iodine constituting less than ⅕ of a total number of halide ions.

As noted above, A in formula (1) can be selected from organic moieties, including monovalent organic cations, such as methylammonium (i.e., CH₃NH₃⁺¹ or more generally alkylammonium in the form of RNH₃⁺¹, where R is an alkyl group, such as a C₁-C₁₀ alkyl group, a C₁-C₅ alkyl group, or a C₁-C₃ alkyl group), formamidinium (i.e., HC(NH₂)₂⁺¹), methylformamidinium (i.e., CH₃C(NH₂)₂⁺¹ or more generally alkylformamidinium in the form of RC(NH₂)₂⁺¹, where R is an alkyl group, such as a C₁-C₁₀ alkyl group, a C₀-C₅ alkyl group, or a C₁-C₃ alkyl group), and guanidinium (i.e., C(NH₂)₃⁺¹), and polyvalent (e.g., divalent) organic cations, such as hydride viologen (i.e., HV⁺²), alkyl viologens (e.g., methyl viologen (i.e., MV⁺²), ethyl viologen (i.e., EV⁺²), heptyl viologen (i.e., C₇V⁺²), and other R-viologens, where R is an alkyl group, such as a C₁-C₁₀ alkyl group, a C₀-C₅ alkyl group, or a C₁-C₃ alkyl group), polymeric viologens, and polyaromatic pyridines.

Multi-phase materials are also contemplated, such as including a primary phase of a halide material represented by formula (1) and a secondary phase. The secondary phase can include, for example, a metal oxide or a metal halide. As another example, the primary phase can include a halide material represented by formula (1), and the secondary phase can include a different halide material represented by formula (1). As another example, the secondary phase can include nanoparticles of varying compositions of formula (1), nanoparticles of tin or another Group 14 element, nanoparticles of an oxide, such as an oxide of tin, nanoparticles of tin, and so forth. It is further contemplated that a blend or a mixture of different halide materials represented by formula (1) can be used.

Dopants can be optionally included in a halide material represented by formula (1), and can be present in amounts that are less than about 5 percent, such as less than about 1 percent or from about 0.1 percent to about 1 percent, in terms of atomic percent or elemental composition. The dopants can derive from reactants that are used to form the halide material, or can derive from moisture, atmospheric gases, or other chemical entities present during the formation of the halide material. The dopants also can be introduced by p-doping processes and n-doping processes, such as by doping with an element of Group 5, such as vanadium, niobium, or tantalum, or an element of Group 15, such as antimony or bismuth to attain an n-type halide material. In some instances, a halide material represented by formula (1) can be intrinsically p-type or can be rendered p-type (or more highly p-type) through doping, and, in other instances, a halide material represented by formula (1) can be intrinsically n-type or can be rendered n-type (or more highly n-type) through doping. The dopants also can be introduced for the purpose of controlling conductivity.

Examples of halide materials represented by formula (1) include those represented with reference to the formula:

[AₐSn_{b}Xₓ][dopants] (2)

In formula (2), A is selected from cesium (or another Group 1 element) and organic moieties; and X is selected from fluorine, chlorine, bromine, and iodine. It is contemplated that a halide material represented by formula (2) can be substantially devoid of iodine to attain a higher bandgap energy, such as where X is selected from elements of Group 17 except iodine. Still referring to formula (2), x can be substantially equal to a+2b (or 2a+2b). In some instances, a can be equal to 1, and x can be substantially equal to 1+2b (or 2+2b). Several halide materials with desirable characteristics can be represented as CsSnX₃[dopants], CsSn₂X₅[dopants], Cs₂SnX₄[dopants], CsSn₃X₇[dopants], Cs₄SnX₆[dopants], and mixtures thereof, as well as halide materials in which at least a fraction of cesium is substituted with an organic moiety.

Additional examples of halide materials represented by formula (1) include those represented with reference to the formula:

[AₐPb_{b}Xₓ][dopants] (3)

In formula (3), A is selected from cesium (or another Group 1 element) and organic moieties; and X is selected from fluorine, chlorine, bromine, and iodine. It is also contemplated that a halide material represented by formula (3) can be substantially devoid of iodine, such as where X is selected from elements of Group 17 except iodine. Still referring to formula (3), x can be substantially equal to a+2b (or 2a+2b). In some instances, a can be equal to 1, and x can be substantially equal to 1+2b (or 2+2b).

Additional examples of halide materials represented by formula (1) include those represented with reference to the formula:

[AₐSn_{b}XₓX′_{x′}][dopants] (4)

In formula (4), A is selected from cesium (or another Group 1 element) and organic moieties; and X and X′ are different and are selected from fluorine, chlorine, bromine, and iodine. Still referring to formula (4), each of x and x′ can be greater than zero, and the sum of x and x′ can be substantially equal to a+2b (or 2a+2b). In some instances, at least one of X and X′ can be iodine, which can constitute at least ⅕, at least ¼, at least ⅓, at least ½, or at least ⅔ of a total number of halide ions. For example, in the case that X is iodine, x/(a+2b) (or x/(2a+2b))≧⅕, ≧¼, ≧⅓, ≧½, or ≧⅔. It is also contemplated that x/(a+2b) (or x/(2a+2b))<⅕. In some instances, a can be equal to 1, and the sum of x and x′ can be substantially equal to 1+2b (or 2+2b). It is also contemplated that a halide material represented by formula (4) can be substantially devoid of iodine to attain a higher bandgap energy, such as where X and X′ are independently selected from elements of Group 17 except iodine.

In the case that A is cesium, X is iodine, and X′ is chlorine, for example, halide materials can be represented as [CsSnI₂Cl][dopants], [CsSnICl₂][dopants], [CsSn₂I₃Cl₂][dopants], [CsSn₂I₂Cl₃][dopants], [CsSn₂I₄Cl][dopants], [CsSn₂ICl₄][dopants], [Cs₂SnI₃Cl][dopants], [Cs₂SnI₂Cl₂][dopants], [Cs₂SnICl₃][dopants], [Cs₄SnI₅Cl][dopants], [Cs₄SnI₄Cl₂][dopants], [Cs₄SnI₃Cl₃][dopants], [Cs₄SnI₂Cl₄][dopants], [Cs₄SnICl₅][dopants], and mixtures thereof, as well as halide materials in which at least a fraction of cesium is substituted with an organic moiety.

And, in the case that A is cesium, X is iodine, and X′ is bromine, for example, halide materials can be represented as [CsSnI₂Br][dopants], [CsSnIBr₂][dopants], [CsSn₂I₃Br₂][dopants], [CsSn₂I₂Br₃][dopants], [CsSn₂I₄Br][dopants], [CsSn₂IBr₄][dopants], [Cs₂SnI₃Br][dopants], [Cs₂SnI₂Br₂][dopants], [Cs₂SnIBr₃][dopants], [Cs₄SnI₅Br][dopants], [Cs₄SnI₄Br₂][dopants], [Cs₄SnI₃Br₃][dopants], [Cs₄SnI₂Br₄][dopants], [Cs₄SnIBr₅][dopants], and mixtures thereof, as well as halide materials in which at least a fraction of cesium is substituted with an organic moiety.

And, in the case that A is cesium, X iodine, and X′ is fluorine, for example, halide materials can be represented as [CsSnI₂F][dopants], [CsSnIF₂][dopants], [CsSn₂I₃F₂][dopants], [CsSn₂I₂F₃][dopants], [CsSn₂I₄F][dopants], [CsSn₂IF₄][dopants], [Cs₂SnI₃F][dopants], [Cs₂SnI₂F₂][dopants], [Cs₂SnIF₃][dopants], [Cs₄SnI₅F][dopants], [Cs₄SnI₄F₂][dopants], [Cs₄SnI₃F₃][dopants], [Cs₄SnI₂F₄][dopants], [Cs₄SnIF₅][dopants], and mixtures thereof, as well as halide materials in which at least a fraction of cesium is substituted with an organic moiety.

Additional examples of luminescent materials represented by formula (1) include those represented with reference to the formula:

[AₐSn_{b}XₓX′_{x′}X″_{x″}][dopants] (5)

In formula (5), A is selected from cesium (or another Group 1 element) and organic moieties; and X, X′, and X″ are different and are selected from fluorine, chlorine, bromine, and iodine. Still referring to formula (5), each of x, x′, and x″ can be greater than zero, and the sum of x, x′, and x″ can be substantially equal to a+2b (or 2a+2b). In some instances, at least one of X, X′, and X″ can be iodine, which can constitute at least ⅕, at least ¼, at least ⅓, at least ½, or at least ⅔ of a total number of halide ions. For example, in the case that X is iodine, x/(a+2b) (or x/(2a+2b))≧⅕, ≧¼, ≧⅓, ≧½, or ≧⅔. It is also contemplated that x/(a+2b) (or x/(2a+2b))<⅕. In some instances, a can be equal to 1, and the sum of x, x′, and x″ can be substantially equal to 1+2b (or 2+2b). It is also contemplated that a halide material represented by formula (5) can be substantially devoid of iodine to attain a higher bandgap energy, such as where X, X′, and X″ are independently selected from elements of Group 17 except iodine.

In the case that A is cesium, X is iodine, X′ is chlorine, and X″ is bromine, for example, a halide material can be represented as:

[CsSnIClBr][dopants] (6)

[CsSn₂ICl_{x′}Br_{4-x′}][dopants], x′=1, 2, or 3 (7)

[CsSn₂I₂Cl_{x′}Br_{3-x′}][dopants], x′=1 or 2 (8)

[CsSn₂I₃ClBr][dopants] (9)

[Cs₂SnICl_{x′}Br_{3-x′}][dopants], x′=1 or 2 (10)

[Cs₂SnI₂ClBr][dopants] (11)

[Cs₄SnICl_{x′}Br_{5-x′}][dopants], x′=1, 2, 3, or 4 (12)

[Cs₄SnI₂Cl_{x′}Br_{4-x′}][dopants], x′=1, 2, or 3 (13)

[Cs₄SnI₃Cl_{x′}Br_{3-x′}][dopants], x′=1 or 2 (14)

[Cs₄SnI₄ClBr][dopants] (15)

Halide materials also can be represented as mixtures of the foregoing, as well as halide materials in which at least a fraction of cesium is substituted with an organic moiety.

And, in the case that A is cesium, X is iodine, X′ is chlorine, and X″ is fluorine, for example, a halide material can be represented as:

[CsSnIClF][dopants] (16)

[CsSn₂ICl_{x′}F_{4-x′}][dopants], x′=1, 2, or 3 (17)

[CsSn₂I₂Cl_{x′}F_{3-x′}][dopants], x′=1 or 2 (18)

[CsSn₂I₃ClF][dopants] (19)

[Cs₂SnICl_{x′}F_{3-x′}][dopants], x′=1 or 2 (20)

[Cs₂SnI₂ClF][dopants] (21)

[Cs₄SnICl_{x′}F_{5-x′}][dopants], x′=1, 2, 3, or 4 (22)

[Cs₄SnI₂Cl_{x′}F_{4-x′}][dopants], x′=1, 2, or 3 (23)

[Cs₄SnI₃Cl_{x′}F_{3-x′}][dopants], x′=1 or 2 (24)

[Cs₄SnI₄ClF][dopants] (25)

Halide materials also can be represented as mixtures of the foregoing, as well as halide materials in which at least a fraction of cesium is substituted with an organic moiety.

Further examples of halide materials represented by formula (1) include those represented with reference to the formula:

[AₐSn_{b}IₓF_{x′}Cl_{x″}Br_{x′″}][dopants] (26)

In formula (26), A is selected from cesium (or another Group 1 element) and organic moieties. Referring to formula (26), each of x, x′, x″, and x′″ can be greater than zero, and the sum of x, x′, x″, and x′″ can be substantially equal to a+2b (or 2a+2b), such that x=(a+2b)−x′−x″−x′″ (or x=(2a+2b)−x′−x″−x′″). In some instances, iodine can constitute at least ⅕, at least ¼, at least ⅓, at least ½, or at least ⅔ of a total number of halide ions. For example, x/(a+2b) (or x/(2a+2b))≧⅕, ≧¼, ≧⅓, ≧½, or ≧⅔. It is also contemplated that x/(a+2b) (or x/(2a+2b))<⅕. In some instances, a can be equal to 1, and the sum of x, x′, x″, and x′″ can be substantially equal to 1+2b (or 2+2b).

Certain halide materials represented by formula (1) can have a perovskite-based microstructure. This perovskite-based microstructure can be layered with relatively stronger chemical bonding within a particular layer and relatively weaker chemical bonding between different layers. In particular, certain halide materials represented by formula (1) can have a perovskite-based crystal structure. This structure can be arranged in the form of a network of BX₆ octahedral units along different planes, with B at the center of each octahedral unit and surrounded by X, and with A interstitial between the planes, where B is a cation, X is a monovalent anion, and A is a cation that serves to balance the total charge and to stabilize the crystal structure.

Dopants can be incorporated in a perovskite-based crystal structure, as manifested by, for example, substitution of a set of atoms included in the structure with a set of dopants. For example, in the case of CsSnI₃, either, or both, Cs⁺¹ and Sn⁺² can be substituted with a cation such as Sn(IV) or Sn⁺⁴, and I⁻¹ can be substituted with an anion such as F⁻¹, Cl⁻¹, Br⁻¹, O⁻², OH⁻¹, or other anions with smaller radii relative to I⁻¹. The incorporation of dopants can alter a perovskite-based crystal structure relative to the absence of the dopants, as manifested by, for example, shorter bond lengths along a particular plane and between different planes, such as shorter B—X—B bond lengths along a particular plane and shorter B—X—B bond lengths between different planes. In some instances, substitution of I⁻¹ with either, or both, of F⁻¹ and Cl⁻¹ can lead to shorter and stronger bonds with respect to Sn⁺² along a particular plane and between different planes. Without being bound by a particular theory, the incorporation of dopants can lend greater stability to a perovskite-based crystal structure, and desirable characteristics can at least partly derive from the presence of these dopants. In some instances, substitution of I⁻¹ with other halides can be at levels greater than typical doping levels, such as up to about 50 percent of I⁻¹ to form an alloy of mixed halides.

Certain halide materials represented by formula (1) can be polycrystalline with constituent crystallites or grains having sizes in the sub-micron range and encompassing the nanometer range. The configuration of grains can vary from one that is quasi-isotropic, namely in which the grains are relatively uniform in shape and size and exhibit a relatively uniform grain boundary orientation, to one that is anisotropic, namely in which the grains exhibit relatively large deviations in terms of shape, size, grain boundary orientation, texture, or a combination thereof. For example, grains can be formed in an anisotropic fashion and with an average size in the range of about 200 nm to about 400 nm, such as from about 250 nm to about 350 nm.

Several halide materials represented by formula (1) have characteristics that are desirable for PV cells. In particular, the halide materials include direct bandgap materials having bandgap energies and resistivities that are tunable to desirable levels by adjusting reactants and processing conditions that are used. For example, a bandgap energy can correlate with A, with the order of increasing bandgap energy corresponding to, for example, cesium, rubidium, potassium, and sodium. As another example, the bandgap energy can correlate with X, with the order of increasing bandgap energy corresponding to, for example, iodine, bromine, chlorine, and fluorine. This order of increasing bandgap energy can translate into an order of decreasing peak emission wavelength. Thus, for example, a halide material including iodine can sometimes exhibit a peak emission wavelength in the range of about 900 nm to about 1 μm, while a halide material including bromine can sometimes exhibit a peak emission wavelength in the range of about 650 nm to about 750 nm. Desirable halide materials include those having bandgap energies in the range of about 0.4 eV to about 5 eV, such as from about 0.4 eV to about 4 eV, from about 0.4 eV to about 3.1 eV, from about 0.4 eV to about 1.99 eV, from about 1 eV to about 1.99 eV, from about 2 eV to about 5 eV, from about 2 eV to about 4 eV, or from about 2 eV to about 3.1 eV. Halide materials having bandgap energies less than about 2 eV can be desirable for absorber layers of PV cells, and halide materials having bandgap energies of about 2 eV or greater can be desirable for emitter layers of PV cells or upper layers in multijunction PV cells.

Examples of halides materials and their associated bandgap energies include CsSnI₃ (about 1.3 eV), CsSnBr₃ (about 1.7 eV), CsSn₂I₄Cl (about 2.2 eV), CsSnCl₃ (about 2.5 eV), Cs₄SnCl₆ (about 2.7 eV), CsSnFCl₂ (about 2.8 eV), and Cs₄SnBr₆ (about 3.4 eV). Additional examples of halides materials and their associated bandgap energies in the range of about 1.25 eV to about 1.7 eV are set forth in Table 1 below:

TABLE 1

| Nominal composition | Bandgap (eV) |
|---|---|
| CsSnCl₂I | about 1.25 |
| CsSnBrI₂ | about 1.46 |
| CsSnBr₂I | about 1.40 |
| Cs₄Sn₃Br₉I | — |
| CsSnBr₃ | about 1.7 |
| CH₃NH₃SnI₃ | about 1.18 |
| CH₃NH₃PbI₃ | about 1.20 |
| HC(NH₂)₂SnI₃ | about 1.50 |
| HC(NH₂)₂PbI₃ | about 1.60 |
| C₁₈NH₃SnI₃ | about 1.37 |
| EVSn₂I₆ | about 1.32 |
| HC(NH₂)₂SnI₂Cl | about 1.30 |
| CH₃NH₃SnI₂Cl | about 1.26 |

Further examples of halides materials and their associated bandgap energies and (hole) conductivities are set forth in Table 2 below:

TABLE 2

| | Absorption edge | Conductivity h |
|---|---|---|
| Nominal Composition | (eV) | (10⁶ Ohm⁻¹ cm⁻¹) |
| Cs₄SnBr₆ (black) | 1.79 | 0.04 |
| Cs₄SnBr₆ (white) | 3.40 | — |
| Cs₄SnBr₄Cl₂ | 1.87 | 0.05 |
| Cs₄SnCl₆ | 2.70 | 0.02 |
| CsSnBr₃ | 1.8 | 9.0 |

### Methods of Forming Halide Materials

Halide materials represented by formula (1) can be formed via reaction of a set of reactants or precursors at high yields and at moderate temperatures and pressures. The reaction can be represented with reference to the formula:

Source(B)+Source(A,X)→Halide Material (27)

In formula (27), source(B) serves as a source of B, and, in some instances, source(B) can also serve as a source of dopants or halide ions. In the case that B is germanium, tin, or lead, for example, source(B) can include one or more types of B-containing compounds selected from B(II) compounds of the form BY, BY₂, BYY′, B₃Y₂, B₃YY′, and B₂Y and B(IV) compounds of the form BY₄ and BYY′Y″Y′″, where Y (and Y′, Y″, and Y′″) can be selected from elements of Group 16, such as oxygen (e.g., as O⁻²); elements of Group 17, such as fluorine (e.g., as F⁻¹), chlorine (e.g., as Cl⁻¹), bromine (e.g., as Br⁻¹), and iodine (e.g., as I⁻¹); and poly-elemental chemical entities, such as nitrate (i.e., NO₃⁻¹), thiocyanate (i.e., SCN⁻¹), hypochlorite (i.e., OCl⁻¹), sulfate (i.e., SO₄⁻²), orthophosphate (i.e., PO₄⁻³), metaphosphate (i.e., PO₃⁻¹), oxalate (i.e., C₂O₄⁻²), methanesulfonate (i.e., CH₃SO₃⁻¹), trifluoromethanesulfonate (i.e., CF₃SO₃⁻¹), and pyrophosphate (i.e., P₂O₇⁻⁴). Examples of tin(II) compounds include tin(II) fluoride (i.e., SnF₂), tin(II) chloride (i.e., SnCl₂), tin(II) chloride dihydrate (i.e., SnCl₂.2H₂O), tin(II) bromide (i.e., SnBr₂), tin(II) iodide (i.e., SnI₂), tin(II) oxide (i.e., SnO), tin(II) sulfate (i.e., SnSO₄), tin(II) orthophosphate (i.e., Sn₃(PO₄)₂), tin(II) metaphosphate (i.e., Sn(PO₃)₂), tin(II) oxalate (i.e., Sn(C₂O₄)), tin(II) methanesulfonate (i.e., Sn(CH₃SO₃)₂), tin(II) pyrophosphate (i.e., Sn₂P₂O₇), and tin(II) trifluoromethanesulfonate (i.e., Sn(CF₃SO₃)₂). Examples of tin (IV) compounds include tin(IV) chloride (i.e., SnCl₄) and tin(IV) chloride pentahydrate (i.e., SnCl₄.5H₂O). It is contemplated that different types of source(B) can be used, such as source(B) and source(B′), with B and B′ independently selected from elements of Group 14, or as source(B), source(B′), and source(B″), with B, B′, and B″ independently selected from elements of Group 14.

Still referring to formula (27), source(A, X) serves as a source of A and X and, in some instances, source(A, X) can also serve as a source of dopants. Examples of source(A, X) include alkali halides of the form AX. In the case that A is cesium, potassium, or rubidium, for example, source(A, X) can include one or more types of A(I) halides, such as cesium(I) fluoride (i.e., CsF), cesium(I) chloride (i.e., CsCl), cesium(I) bromide (i.e., CsBr), cesium(I) iodide (i.e., CsI), potassium(I) fluoride (i.e., KF), potassium(I) chloride (i.e., KCl), potassium(I) bromide (i.e., KBr), potassium(I) iodide (i.e., KI), rubidium(I) fluoride (i.e., RbF), rubidium(I) chloride (i.e., RbCl), rubidium(I) bromide (i.e., RbBr), and rubidium(I) iodide (i.e., RbI). Additional examples of source(A, X) include organohalides, such as in which cesium, potassium, and rubidium of the foregoing examples are substituted with organic moieties, as well as organohalides of the form AX₂, where A is a divalent organic cation. It is contemplated that different types of source(A, X) can be used, such as source(A, X) and source(A′, X′), with A and A′ independently selected from elements of Group 1 and organic moieties, and X and X′ independently selected from elements of Group 17, or as source(A, X), source(A′, X′), and source(A′, X″), with A, A′, and A″ independently selected from elements of Group 1 and organic moieties, and X, X′, and X″ independently selected from elements of Group 17.

The reaction represented by formula (27) can be carried out by combining, mixing, or otherwise contacting source(B) with source(A, X), and then applying a form of energy. For some embodiments, source(B) and source(A, X) can be deposited on a substrate to form a set of films or layers. For example, source(B) and source(A, X) can be co-deposited on a substrate to form a film, or can be sequentially deposited to form adjacent films. Examples of suitable deposition techniques include vacuum deposition (e.g., thermal evaporation or electron-beam evaporation), Physical Vapor Deposition (“PVD”), Chemical Vapor Deposition (“CVD”), Atomic Layer Deposition (“ALD”), and sputtering. For other embodiments, source(B) and source(A, X) can be mixed in a dry form, in solution, or in accordance with any other suitable mixing technique. For example, source(B) and source(A, X) can be provided in a powdered form, and can be mixed using any suitable dry mixing technique. As another example, source(B) and source(A, X) can be dispersed in a reaction medium to form a reaction mixture, and the reaction medium can include a solvent or a mixture of solvents. Once source(B) and source(A, X) are suitably combined, a form of energy is applied to promote formation of a halide material, such as in the form of acoustic or vibrational energy, electrical energy, magnetic energy, mechanical energy, optical energy, or thermal energy. For example, source(B) and source(A, X) can be solution-deposited on a substrate, such as by spray coating, dip coating, web coating, wet coating, or spin coating, and a resulting set of films can be heated to a suitable temperature to form the halide material. Heating can be performed in air, in an inert atmosphere (e.g., a nitrogen atmosphere), or in a reducing atmosphere for a suitable time period. It is also contemplated that multiple forms of energy can be applied simultaneously or sequentially. As another example, source(B) and source(A, X) can be initially reacted to form a halide material, which is then subjected to grinding or other processing to attain a powdered form of the halide material. Next, the powdered halide material can be dispersed in a solvent or a mixture of solvents, and then solution-deposited on a substrate. A resulting set of films can be heated to a suitable temperature to remove the solvent or the mixture of solvents.

The resulting halide material can include A, B, and X as major elemental components as well as elemental components derived from or corresponding to Y. Also, the halide material can include additional elemental components, such as carbon, chlorine, hydrogen, and oxygen, that can be present in amounts that are less than about 5 percent or less than about 1 percent in terms of elemental composition, and further elemental components, such as sodium, sulfur, phosphorus, and potassium, that can be present in trace amounts that are less than about 0.1 percent in terms of elemental composition.

Examples of the reaction represented by formula (27) include those represented with reference to the formula:

BY₂+AX→Halide Material (28)

BY₂+AX₂→Halide Material (29)

In formulas (28)-(29), B is selected from germanium, tin, and lead; Y is selected from fluorine, chlorine, bromine, and iodine; A is selected from potassium, rubidium, and cesium; and X is selected from fluorine, chlorine, bromine, and iodine. Still referring to formulas (28)-(29), it is contemplated that BY₂ can be more generally represented as BY₂ and B′Y′₂ (or BY₂, B′Y′₂, and B″Y″₂), where B and B′ (or B, B′, and B″) are independently selected from germanium, tin, and lead, and Y and Y′ (or Y, Y′, and Y″) are independently selected from fluorine, chlorine, bromine, and iodine. In the case that B is tin, for example, BY₂ can be represented as SnY₂, or can be more generally represented as SnY₂ and SnY′₂ (or SnY₂, SnY′₂, and SnY″₂), where Y and Y (or Y, Y′, and Y″) are independently selected from fluorine, chlorine, bromine, and iodine.

For example, source(B) and source(A, X) can be subjected to vacuum deposition, thereby forming a precursor layer over a substrate. Deposition can be carried out using a vacuum deposition system that is evacuated to a pressure no greater than about 1×10⁻⁴ Torr, such as no greater than about 1×10⁻⁵ Torr, and down to about 1×10⁻⁶ Torr or less. It is contemplated that another suitable deposition technique can be used in place of, or in conjunction with, vacuum deposition.

Deposition of source(B) and source(A, X) can be carried out sequentially in accordance with the same vacuum deposition technique or different vacuum deposition techniques. For example, BY₂ and AX can be evaporated in sequential layers, from two layers to 30 or more layers total, such as from two layers to 16 layers total, or from two layers to six layers total, and with a weight or molar ratio of BY₂ to AX from about 99:1 to about 1:99, such as from about 5:1 to about 1:5 or from about 2:1 to about 1:2. A particular one of BY₂ and AX having a lower melting point Tₘ₁ can be placed in an evaporator boat and deposited by thermal evaporation, while another one of BY₂ and AX having a higher melting point Tₘ₂ can be placed in another evaporator boat and deposited by thermal evaporation or electron-beam evaporation. In the case of SnI₂ with a melting point of about 318° C. (or SnCl₂ with a melting point of about 246° C.) and CsI with a melting point of about 620° C., SnI₂ (or SnCl₂) can be deposited by thermal evaporation, while CsI can be deposited by thermal evaporation or electron-beam evaporation. A thickness of each individual BY₂-containing layer or each individual AX-containing layer can be in the range of about 10 nm to about 1.5 μm, such as from about 10 nm to about 1 μm or from about 10 nm to about 300 nm, with a total thickness for all layers in the range of about 20 nm to about 45 μm, such as from about 40 nm to about 20 μm or from about 50 nm to about 5 μm.

Source(B) and source(A, X) can also be co-deposited in accordance with a particular vacuum deposition technique. For example, BY₂ and AX can be co-evaporated to form a single layer or multiple layers, with a weight or molar ratio of BY₂ to AX from about 10:1 to about 1:10, such as from about 5:1 to about 1:5 or from about 2:1 to about 1:2, and with a total thickness in the range of about 10 nm to about 1.5 μm, such as from about 10 nm to about 1 μm or from about 10 nm to about 300 nm. In particular, BY₂ and AX can be mixed in an evaporator boat and then deposited by thermal evaporation. Mixing of BY₂ and AX can be carried out in a powdered form, or by forming a pre-melt of BY₂ and AX. In the case of SnI₂ (or SnCl₂) and CsI, SnI₂ (or SnCl₂) can evaporate at lower temperatures than CsI, and, therefore, a temperature of the evaporator boat can be gradually raised as a relative amount of CsI in a mixture increases.

Different types of source(B) can be used, and can be co-deposited with source(A, X) or deposited sequentially with source(A, X). For example, BY₂ and B′Y′₂ can be mixed in an evaporator boat and deposited by thermal evaporation, followed by deposition of AX, and so forth. Mixing of BY₂ and B′Y′₂ can be carried out in a powdered form, or by forming a pre-melt of BY₂ and B′Y′₂, with a weight or molar ratio of BY₂ to B′Y′₂ from about 99:1 to about 1:99, such as from about 5:1 to about 1:5 or from about 2:1 to about 1:2. As another example, BY₂, B′Y′₂, and B″Y″₂ can be mixed in an evaporator boat and deposited by thermal evaporation, followed by deposition of AX, and so forth. Likewise, different types of source(A, X) can be used, and can be co-deposited with source(B) or deposited sequentially with source(B).

Next, the precursor layer can be subjected to annealing to promote reaction according to formula (27), thereby converting the precursor layer to the layer of a halide material. Annealing can be carried out using any suitable heating technique to apply thermal energy via conduction, convection, or radiation heating, such as by heating the assembly of layers using a hot plate, an oven, resist heating, or lamp heating. It is also contemplated that thermal energy can be applied in accordance with fast heating cycles to yield rapid thermal annealing.

In some implementations, an annealing temperature and an annealing time period can be optimized to yield improved characteristics for use in a PV cell. For example, a particular one of BY₂ and AX can have a lower melting point Tₘ₁, another one of BY₂ and AX can have a higher melting point Tₘ₂, and an optimal annealing temperature Tₕₑₐₜ can be greater than Tₘ₁ and less than Tₘ₂, such as greater than Tₘ₁ and up to a three-quarters point (i.e., (Tₘ₁+3Tₘ₁₂)/4) or a halfway point (i.e., (Tₘ₁+Tₘ₁₂)/2) between the lower melting point and the higher melting point, although annealing can also be carried out at higher or lower temperatures. In the case of SnI₂ with a melting point of about 318° C. and CsI with a melting point of about 620° C., an optimal annealing temperature Tₕₑₐₜ can be greater than about 318° C. and less than about 620° C., such as from about 340° C. to about 420° C. or from about 350° C. to about 410° C. In the case of SnCl₂ with a melting point of about 246° C. and CsI with a melting point of about 620° C., an optimal annealing temperature Tₕₑₐₜ can be greater than about 246° C. and less than about 620° C. In some instances, an initial melting can arise from formation of an eutectic between SnCl₂ and a reaction product of SnCl₂ and CsI. An optimal annealing time period can be in the range of about 1 sec to about 1 hr, such as from about 5 sec to about 10 min or from about 5 sec to about 1 min, although annealing can also be carried out for longer or shorter time periods. Optimal values of an annealing temperature and an annealing time period can also be suitably adjusted depending upon, for example, particular reactants used, a thickness of individual layers within the precursor layer, or a total thickness of the precursor layer. In some instances, a reaction between layers of reactants can occur at temperatures significantly below melting temperatures of the reactants by way of solid state reactions. In particular, the layers can be sufficiently thin so that diffusion can occur within, for example, a few hundred nanometers or less and a time period of a few seconds to a few minutes, thereby allowing the reactants to react and to form the halide material.

### PV Cells

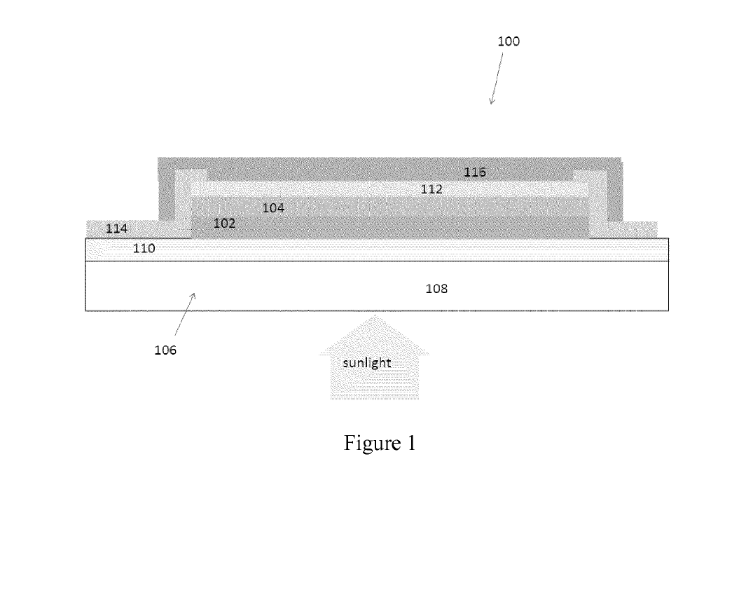

FIG. 1 illustrates a dye-sensitized PV cell 100 implemented in accordance with an embodiment of the disclosure. The PV cell 100 includes a porous layer 102 of a semiconductor oxide, such as TiO₂, SnO₂, or ZnO, and a photosensitizing dye 104 is deposited on the porous, semiconductor oxide layer 102. The porous, semiconductor oxide layer 102 can be deposited in the form of nanoparticles of the semiconductor oxide, and the photosensitizing dye 104, such as a Ru complex photosensitizing dye or other suitable dye, can be adsorbed onto the nanoparticles of the semiconductor oxide. The porous, semiconductor oxide layer 102 along with the adsorbed dye 104 serve as a photoactive layer of the PV cell. As illustrated in FIG. 1, the porous, semiconductor oxide layer 102 is deposited on a substrate 106, which serves as a mechanical supporting structure during manufacturing operations and subsequent use. In the illustrated implementation, the substrate 106 faces incident sunlight, and includes a base substrate 108 formed of an optically transparent material, such as a glass, a polymer, or another suitable optically transparent material. The substrate 106 also includes a bottom conductive layer 110 that is deposited on the base substrate 108 to serve as a front contact. The bottom conductive layer 110 can be formed of a transparent conductive oxide, such as ZnO (e.g., aluminum doped-ZnO), TiO₂ (e.g., fluorine doped-TiO₂), SnO₂ (e.g., fluorine doped-SnO₂), ITO (i.e., indium tin oxide), SrTiO₃, BaTiO₃, or another titanate, as well as nanostructures, such as carbon nanotubes.

A p-type halide material, such as one described above, is deposited on the porous, semiconductor oxide layer 102 with the adsorbed dye 104, and serves as a hole transporting layer 112. The inclusion of the p-type halide material allows a liquid electrolyte to be omitted, thereby affording improved long-term performance and stability that otherwise can be adversely impacted through the use of corrosive and volatile liquid electrolytes. The p-type halide material can be deposited by vacuum deposition or solution deposition. The deposition order of the p-type halide material and the porous, semiconductor oxide layer 102 can be reversed for other implementations.

Next, and still referring to FIG. 1, an insulator is deposited on the assembly of stacked layers on the substrate 106, such as by atomic layer deposition, plasma-enhanced chemical vapor deposition, or sputtering, thereby forming an encapsulation layer 114. The encapsulation layer 114 extends along and covers a top surface of the substrate 106, side surfaces of the assembly of layers (including side surfaces of the layer 112 of the p-type halide material), and a top surface of the layer 112 of the p-type halide material, while leaving at least one aperture or window for subsequent deposition of a conductive material. Examples of suitable insulators for the encapsulation layer include oxides, such as silica, alumina, TiO₂, Ta₂O₅, Nb₂O₅, ZrO₂, HfO₂, SnO₂, ZnO₂, La₂O₃, Y₂O₃, CeO₂, Se₂O₃, Er₂O₃, V₂O₅, and In₂O₃; nitrides, such as SiOₓN₂₋ₓ; fluorides, such as CaF₂, SrF₂, ZnF₂, MgF₂, LaF₃, and GdF₂; nanolaminates, such as HfO₂/Ta₂O₅, TiO₂/Ta₂O₅, TiO₂/Al₂O₃, ZnS/Al₂O₃, and AlTiO; and other suitable thin-film dielectric materials. Additional examples of suitable insulators include glasses, such as borosilicate glasses, phosphate glasses, and other low melting glasses. A thickness of the encapsulation layer 114 can be in the range of about 10 nm to about 1.5 μm, such as from about 50 nm to about 500 nm or from about 50 nm to about 300 nm.

A top conductive layer 116 is then deposited on the assembly layers on the substrate 106 to serve as a back contact. The back contact can be selectively deposited in the aperture or window defined by the encapsulation layer 114, but also can extend beyond the aperture or window and along a top surface and side surfaces of the encapsulation layer 114. The encapsulation layer 114 along with the back contact serve to provide protection and hermetic sealing of the p-type halide material and to reduce its exposure to oxygen, humidity, and other contaminants, thereby enhancing stability of resulting PV performance characteristics. The back contact can be formed of a metal, such as silver, aluminum, gold, copper, iron, cobalt, nickel, palladium, platinum, ruthenium, or iridium, a metal alloy, or another conductive material that is substantially non-reactive with the halide material and can form an Ohmic contact with the halide material.

It is also contemplated that the photosensitizing dye 104 can be optionally omitted for certain implementations, with the semiconductor oxide layer 102 (or a layer formed of another suitable material having a bandgap energy of about 2 eV or greater) serving as an emitter layer, and the layer 112 of the p-type halide material serving as an absorber layer. For example, a layer of a higher bandgap energy material and the layer 112 of the p-type halide material can form a p-n heterojunction, such as in the case of the p-type halide material and an n-type semiconductor oxide, a p-n heterojunction, such as in the case of the p-type halide material and a different halide material that is n-type, a p-n homojunction, such as in the case of the p-type halide material and the same halide material that is doped to render it n-type, or a heterojunction that is homotype, such as in the case of two different p-type halide materials with different bandgap energies. In the latter case, charge transport can be based on majority carrier, and can be less sensitive to defects and recombinations. As another example, a layer of a higher bandgap energy halide material can serve as an emitter layer, and a layer of a germanium-based polymer (e.g., a polygermane or a polygermyne (evaporated) with a bandgap energy of about 0.7 eV) can serve as an absorber layer. Further details on homojunction and heterojunction PV cells are provided below. It is also contemplated that a set of barrier layers can be incorporated in the assembly layers.

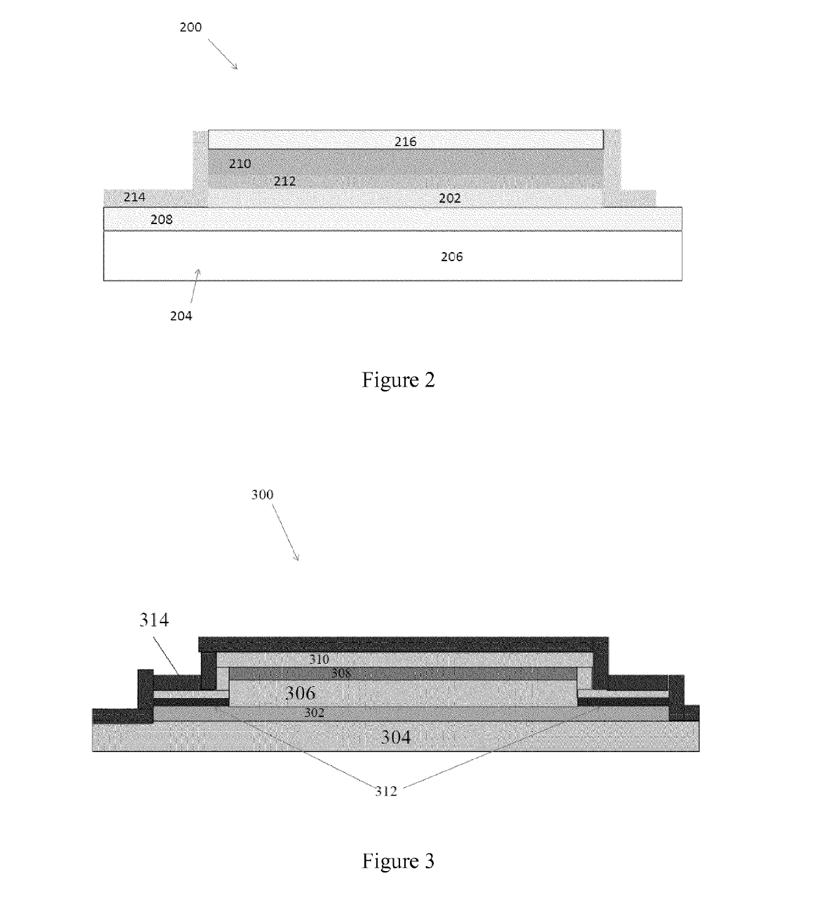

FIG. 2 illustrates a dye-sensitized PV cell 200 implemented in accordance with another embodiment of the disclosure. The PV cell 200 includes a layer 202 of a p-type halide material, which serves as a hole transporting layer. The p-type halide material can be deposited by vacuum deposition or solution deposition. The layer 202 of the p-type halide material is deposited on a substrate 204, which serves as a mechanical supporting structure during manufacturing operations and subsequent use. In the illustrated implementation, the substrate 204 includes a base substrate 206 formed of an optically transparent, translucent, or opaque material, such as a glass, a ceramic, a metal, a polymer, or another suitable supporting material. The substrate 204 also includes a bottom conductive layer 208 that is deposited on the base substrate 206 to serve as a back contact. The conductive layer 208 can be formed of a transparent conductive oxide, nanostructures, a metal, a metal alloy, or another conductive material that is substantially non-reactive with the halide material and can form an Ohmic contact with the halide material.

The PV cell 200 also includes a porous layer 210 of a semiconductor oxide and a photosensitizing dye 212, which can be adsorbed onto the semiconductor oxide. As illustrated in FIG. 2, the porous, semiconductor oxide layer 210 along with the adsorbed dye 212 are deposited on the layer 202 of the p-type halide material. The porous, semiconductor oxide layer 210 along with the adsorbed dye 212 serve as a photoactive layer of the PV cell 200. The deposition order of the p-type halide material and the porous, semiconductor oxide layer 210 can be reversed for other implementations.

Still referring to FIG. 2, an insulator is deposited on the assembly of stacked layers on the substrate 204, thereby forming an encapsulation layer 214. The encapsulation layer 214 extends along and covers a top surface of the substrate 204 and side surfaces of the assembly of layers (including side surfaces of the layer 202 of the p-type halide material), while leaving at least one aperture or window for subsequent deposition of a conductive material. A top conductive layer 216 is then deposited on the assembly of layers on the substrate 204 to serve as a front contact. The front contact can be selectively deposited in the aperture or window defined by the encapsulation layer 214, but also can extend beyond the aperture or window and along a top surface and side surfaces of the encapsulation layer 214. The encapsulation layer 214 along with the top contact serve to provide protection and hermetic sealing of the p-type halide material and to reduce its exposure to oxygen, humidity, and other contaminants, thereby enhancing stability of resulting PV performance characteristics. The front contact can be formed of a transparent conductive oxide, as well as nanostructures.

It is also contemplated that the photosensitizing dye 212 can be optionally omitted for certain implementations, with the semiconductor oxide layer 210 (or a layer formed of another suitable material having a bandgap energy of about 2 eV or greater) serving as an emitter layer, and the layer 202 of the p-type halide material serving as an absorber layer. For example, a layer of the higher bandgap energy material and the layer 202 of the p-type halide material can form a p-n heterojunction, a p-n homojunction, or a heterojunction that is homotype. As another example, a layer of a higher bandgap energy halide material can serve as an emitter layer, and a layer of a germanium-based polymer can serve as an absorber layer. Further details on homojunction and heterojunction PV cells are provided below. It is also contemplated that a set of barrier layers can be incorporated in the assembly layers. Certain aspects of the PV cell 200 of FIG. 2 can be implemented in a similar manner as described in connection with FIG. 1, and those aspects are not repeated.

FIG. 3 illustrates a thin-film heterojunction PV cell 300 implemented in accordance with another embodiment of the disclosure. The PV cell 300 includes a bottom conductive layer 302 that is deposited on a substrate 304, which can be formed of an optically transparent, translucent, or opaque material. Depending upon the particular implementation, the bottom conductive layer 302 can serve as a back contact and can be formed of a suitable back contact, conductive material, or can serve as a front contact and can be formed of a suitable front contact, conductive material. The PV cell 300 also includes a layer 306 of a p-type halide material, which serves as a p-type absorber layer. The p-type halide material can be deposited by vacuum deposition or solution deposition on the bottom conductive layer 302. Although not illustrated, a hole transporting layer can be included between the p-type halide material and the bottom conductive layer 302.

The PV cell 300 also includes a layer 308 of a semiconductor oxide, which is deposited on the layer 306 of the p-type halide material. The semiconductor oxide layer 308 serves as an n-type emitter layer, and forms a p-n heterojunction with the layer 306 of the p-type halide material. In other words, the layer 306 of the p-type halide material and the semiconductor oxide layer 308 serve as photoactive layers of the PV cell 300. The deposition order of the p-type halide material and the semiconductor oxide layer 308 can be reversed for other implementations. Examples of suitable materials for the n-type emitter layer include semiconductor oxides, such as ZnO (e.g., aluminum doped-ZnO) and TiO₂ (e.g., fluorine doped-TiO₂), amorphous silicon, microcrystalline silicon, CdS, CdSe, ZnS, and other semiconductor materials having a bandgap energy of about 2 eV or greater. Also, the same or a different halide material that is n-type can be deposited as the n-type emitter layer, and can form a p-n homojunction or heterojunction with the layer 306 of the p-type halide material. Moreover, two different p-type halide materials with different bandgap energies can form a heterojunction that is homotype. As another example, a layer of a higher bandgap energy halide material can serve as an emitter layer, and a layer of a germanium-based polymer can serve as an absorber layer.

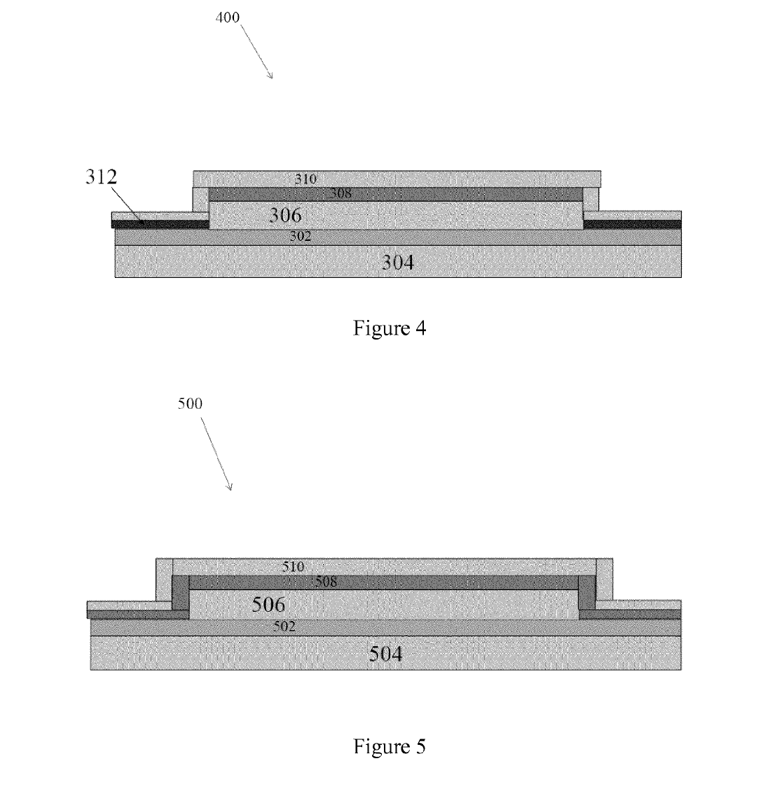

Still referring to FIG. 3, a top conductive layer 310 is deposited on the assembly of stacked layers on the substrate 304. Depending upon the particular implementation, the top conductive layer 310 can serve as a back contact and can be formed of a suitable back contact, conductive material, or can serve as a front contact and can be formed of a suitable front contact, conductive material. The top conductive layer 310 extends along and covers a top surface of the semiconductor oxide layer 308 and side surfaces of the assembly of layers (including side surfaces of the layer 306 of the p-type halide material). As illustrated in FIG. 3, a spacer layer 312 is deposited around a periphery of the layer 306 of the p-type halide material, and is formed of a suitable insulator to mitigate against electrical contact between the top and bottom conductive layers 310 and 302. Next, an insulator is deposited on the assembly of layers on the substrate 304, thereby forming an encapsulation layer 314. The encapsulation layer 314 extends along and covers exposed surfaces of the substrate 304 and the assembly of layers (including a top surface and side surfaces of the top conductive layer 310). The top conductive layer 310 along with the spacer layer 312 and the encapsulation layer 314 serve to provide protection and hermetic sealing of the p-type halide material and to reduce its exposure to oxygen, humidity, and other contaminants, thereby enhancing stability of resulting PV performance characteristics. It is also contemplated that the encapsulation layer 314 can be omitted for other implementations. One such implementation (with the encapsulation layer omitted) is illustrated in FIG. 4. It is also contemplated that a set of barrier layers can be incorporated in the assembly layers. Certain aspects of the PV cells 300 and 400 of FIGS. 3-4 can be implemented in a similar manner as described in connection with FIGS. 1-2, and those aspects are not repeated.

FIG. 5 illustrates a thin-film heterojunction PV cell 500 implemented in accordance with another embodiment of the disclosure. The PV cell 500 includes a bottom conductive layer 502 that is deposited on a substrate 504, which can be formed of an optically transparent, translucent, or opaque material. Depending upon the particular implementation, the bottom conductive layer 502 can serve as a back contact and can be formed of a suitable back contact, conductive material, or can serve as a front contact and can be formed of a suitable front contact, conductive material. The PV cell 500 also includes a layer 506 of a p-type halide material, which serves as a p-type absorber layer. The p-type halide material can be deposited by vacuum deposition or solution deposition on the bottom conductive layer 502. Although not illustrated, a hole transporting layer can be included between the p-type halide material and the bottom conductive layer 502.

The PV cell 500 also includes a layer 508 of a semiconductor oxide, which is deposited on the layer 506 of the p-type halide material. The semiconductor oxide layer 508 serves as an n-type emitter layer, and forms a p-n heterojunction with the layer 506 of the p-type halide material. In other words, the layer 506 of the p-type halide material and the semiconductor oxide layer 508 serve as photoactive layers of the PV cell 500. The deposition order of the p-type halide material and the semiconductor oxide layer 508 can be reversed for other implementations. Examples of suitable materials for the n-type emitter layer include semiconductor oxides, amorphous silicon, microcrystalline silicon, CdS, CdSe, ZnS, and other semiconductor materials having a bandgap energy of about 2 eV or greater. Also, the same or a different halide material that is n-type can be deposited as the n-type emitter layer, and can form a p-n homojunction or heterojunction with the layer 506 of the p-type halide material. Moreover, two different p-type halide materials with different bandgap energies can form a heterojunction that is homotype. As another example, a layer of a higher bandgap energy halide material can serve as an emitter layer, and a layer of a germanium-based polymer can serve as an absorber layer.

Still referring to FIG. 5, the emitter layer 508 extends along and covers a top surface and side surfaces of the layer 506 of the p-type halide material. The emitter layer 508 also extends along a top surface of the bottom conductive layer 502 and around a periphery of the layer 506 of the p-type halide material, thereby mitigating against electrical contact between the bottom conductive layer 502 and a top conductive layer 510 that is deposited on the assembly of stacked layers on the substrate 504. Depending upon the particular implementation, the top conductive layer 510 can serve as a back contact and can be formed of a suitable back contact, conductive material, or can serve as a front contact and can be formed of a suitable front contact, conductive material. The top conductive layer 510 extends along and covers a top surface and side surfaces of the emitter layer 508. The emitter layer 508 along with the top conductive layer 510 serve to provide protection and hermetic sealing of the p-type halide material and to reduce its exposure to oxygen, humidity, and other contaminants, thereby enhancing stability of resulting PV performance characteristics. It is also contemplated that an encapsulation layer can be included for other implementations, such as by depositing an insulator on exposed surfaces of the substrate 504 and the assembly of layers. It is also contemplated that a set of barrier layers can be incorporated in the assembly layers. Certain aspects of the PV cell 500 of FIG. 5 can be implemented in a similar manner as described in connection with FIGS. 1-4, and those aspects are not repeated.

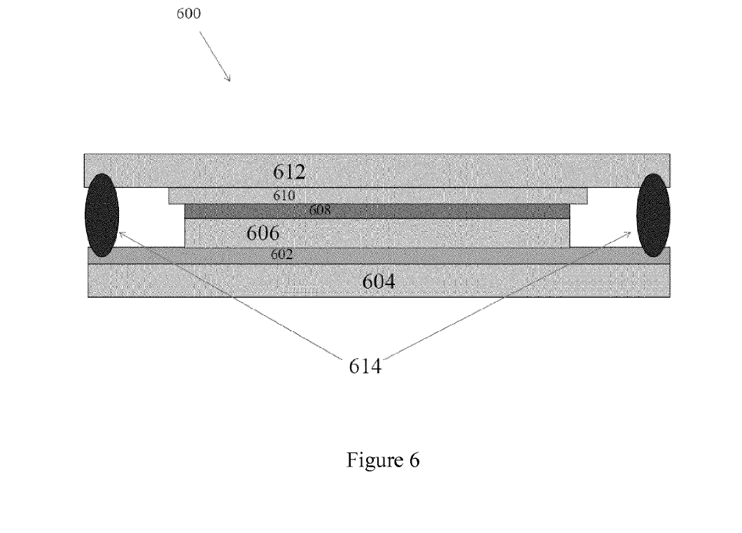

FIG. 6 illustrates a thin-film heterojunction PV cell 600 implemented in accordance with another embodiment of the disclosure. The PV cell 600 includes a bottom conductive layer 602 that is deposited on a bottom substrate 604, which can be formed of an optically transparent, translucent, or opaque material. Depending upon the particular implementation, the bottom conductive layer 602 can serve as a back contact and can be formed of a suitable back contact, conductive material, or can serve as a front contact and can be formed of a suitable front contact, conductive material. The PV cell 600 also includes a layer 606 of a p-type halide material, which serves as a p-type absorber layer. The p-type halide material can be deposited by vacuum deposition or solution deposition on the bottom conductive layer 602. Although not illustrated, a hole transporting layer can be included between the p-type halide material and the bottom conductive layer 602.

The PV cell 600 also includes a layer 608 of a semiconductor oxide, which is deposited on the layer 606 of the p-type halide material. The semiconductor oxide layer 608 serves as an n-type emitter layer, and forms a p-n heterojunction with the layer 606 of the p-type halide material. In other words, the layer 606 of the p-type halide material and the semiconductor oxide layer 608 serve as photoactive layers of the PV cell 600. The deposition order of the p-type halide material and the semiconductor oxide layer 608 can be reversed for other implementations. Examples of suitable materials for the n-type emitter layer include semiconductor oxides, amorphous silicon, microcrystalline silicon, CdS, CdSe, ZnS, and other semiconductor materials having a bandgap energy of about 2 eV or greater. Also, the same or a different halide material that is n-type can be deposited as the n-type emitter layer, and can form a p-n homojunction or heterojunction with the layer 606 of the p-type halide material. Moreover, two different p-type halide materials with different bandgap energies can form a heterojunction that is homotype. As another example, a layer of a higher bandgap energy halide material can serve as an emitter layer, and a layer of a germanium-based polymer can serve as an absorber layer.

Still referring to FIG. 6, a top conductive layer 610 is deposited on the emitter layer 608. Depending upon the particular implementation, the top conductive layer 610 can serve as a back contact and can be formed of a suitable back contact, conductive material, or can serve as a front contact and can be formed of a suitable front contact, conductive material.

As illustrated in FIG. 6, a top substrate 612 is affixed to the assembly of stacked layers on the bottom substrate 604, such as by lamination or bonding via an adhesive applied to a top surface of the top conductive layer 610. A sealing structure 614, such as in the form of an O-ring or a ring of a solder material, extends between the top and bottom substrates 612 and 604 and surrounds side surfaces of the assembly of layers, thereby providing protection and hermetic sealing of the p-type halide material to reduce its exposure to oxygen, humidity, and other contaminants. An aperture defined by the sealing structure 614 can be substantially circular, substantially square-shaped, substantially rectangular, or other geometric or non-geometric shapes. It is contemplated that a sealing structure can be included in other PV cell designs, such as the dye-sensitized PV cells 100 and 200 illustrated in FIGS. 1-2. It is also contemplated that an encapsulation layer can be included for other implementations, such as by depositing an insulator on exposed surfaces of an assembly of layers, in combination with the use of a sealing structure. It is also contemplated that a set of barrier layers can be incorporated in the assembly layers. Certain aspects of the PV cell 600 of FIG. 6 can be implemented in a similar manner as described in connection with FIGS. 1-5, and those aspects are not repeated.

The halide materials described herein also can be included in multijunction PV cells. Multijunction PV cells can attain higher efficiencies for solar energy conversion, such as with efficiencies greater that about 40%. However, high fabrication costs have impeded their widespread use as a source of renewable electricity. The halide materials described herein can be synthesized with a wide range of bandgap energies and high electrical conductivity from abundant, low cost reactants. These solution processable materials can be the basis of low cost, high efficiency, multijunction PV cells.

PV cells are typically single junction, and mostly based on silicon. A single junction cell typically has a characteristic bandgap that determines the maximum theoretical efficiency for the cell. An incident photon with energy greater than the bandgap will be absorbed and converted to electrical energy. The maximum efficiency can be achieved for photon energy at or near the bandgap, and energy in excess of the bandgap typically will be lost as heat. Photons with energy less than the bandgap typically will not be absorbed. The maximum theoretical efficiency for a single junction PV cell is about 37%, with single junction silicon cells (with a bandgap of about 1.1 eV) having an efficiency of about 31%. The solar spectrum extends from about 4 eV into the far infrared. Multijunction PV cells can divide the solar spectrum into spectral regions by employing materials with separate bandgaps or absorption regions. The separate materials can each absorb light with energy closer to the bandgap and waste less energy as heat. A two junction cell employs two separate absorber materials to sequentially absorb the higher energy light and then the lower energy light that passes through a first cell. The procedure can be repeated multiple times to give a finer splitting of the solar spectrum and higher efficiencies. The theoretical efficiencies are: single junction, about 37%; two junctions, about 50%; three junctions, about 56%; and 36 junctions, about 72%. These theoretical efficiencies can depend on proper matching of bandgaps.

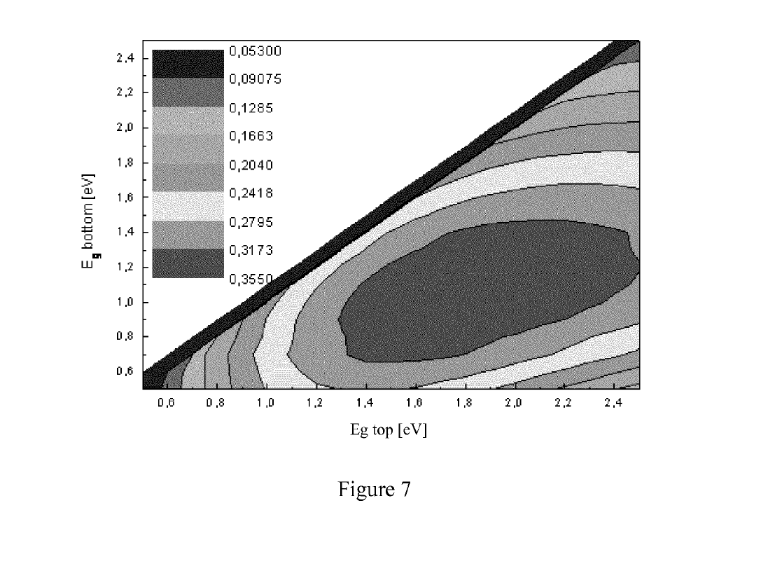

Certain embodiments of the disclosure relate to low cost, high efficiency, multijunction PV technology using low temperature, solution processing of a class of halide materials as described herein. Halide materials belonging to this class can readily form polycrystalline films when deposited from solution (or by thermal evaporation). These materials have conductivities that are suitable for making junctions for PV cells. For example, multijunction PV cells can be based on a structure with TiO₂ as an emitter and various cesium-tin-halides as absorbers. As an example, the theoretical efficiency for a two junction device with absorber bandgap layers of about 1.2 eV and about 1.7 eV can be about 35% (see FIG. 7). As another example, a multijunction PV cell can have a theoretical efficiency of about 60% for a three junction device with bandgaps of about 2.2 eV, about 1.2 eV, and about 0.67 eV.

The fabrication of multijunction PV cells can involve the proper selection of absorber materials to efficiently use the solar spectrum, as well as the interconnection of individual cells in a cost effect manner. Low cost fabrication can involve a monolithic structure. The individual subcells can be stacked in the device. Arrangements of connecting the individual subcells include: two, three, and four terminal connections. The three and four terminal cell interconnection can be the simplest from a cell material standpoint, but more demanding in fabricating the interconnects. The three and four terminal interconnection typically involves individual connections for each subcell. This can be attained with selective depth laser scribing and conductive ink technology. The tradeoff is extra processing steps and non-functional area from the scribe and interconnects. In a three terminal two junction device, the junctions can be reversed and share a common emitter.

The two terminal connections can add the voltage from the subcells, and can be most compatible with the technology of monolithic interconnects. This involves matching of currents and tunnel junctions between stacked cells.

For voltage addition from stacked subcells, a low resistance, optically transparent interconnect can be made between the stacked subcells. For these interconnects, current can flow from an n-type semiconductor layer into a p-type semiconductor layer, and tunnel junctions can be used for joining the stacked subcells. High conductivity (short depletion region) materials are desirable for this junction.

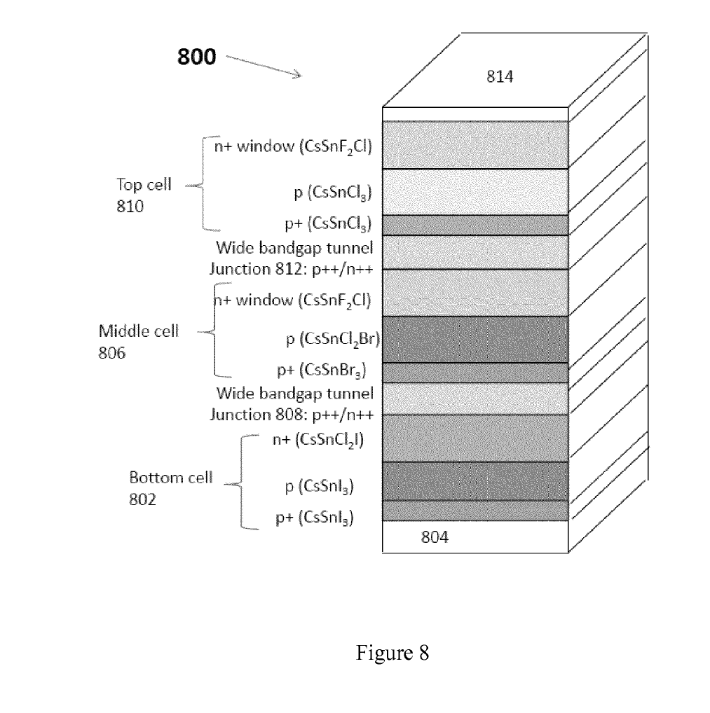

FIG. 8 below illustrates a multijunction PV cell 800 implemented in accordance with another embodiment of the disclosure. The PV cell 800 is a triple junction cell with varying bandgap materials that are stacked. The PV cell 800 includes a bottom cell 802, which includes various layers that are stacked on a bottom conductive layer 804 serving as a back contact. Specifically, the bottom cell 802 includes a window layer of a n⁺-type halide material (here, CsSnCl₂I), an absorber layer of a p-type halide material (here, CsSnI₃), and a hole transporting layer of a p⁺-type halide material (here, CsSnI₃). The PV cell 800 also includes a middle cell 806, which includes various layers that are stacked on a tunnel junction layer 808 interconnecting the middle cell 806 and the bottom cell 802. Specifically, the middle cell 806 includes a window layer of a n⁺-type halide material (here, CsSnF₂Cl), an absorber layer of a p-type halide material (here, CsSnCl₂Br), and a hole transporting layer of a p⁺-type halide material (here, CsSnBr₃). The PV cell 800 also includes a top cell 810, which includes various layers that are stacked on a tunnel junction layer 812 interconnecting the top cell 810 and the middle cell 806. Specifically, the top cell 810 includes a window layer of a n⁺-type halide material (here, CsSnF₂Cl), an absorber layer of a p-type halide material (here, CsSnCl₃), and a hole transporting layer of a p⁺-type halide material (here, CsSnCl₃). As illustrated in FIG. 8, a top conductive layer 814 is deposited on the top cell 810, and serves as a front contact.

Other implementations and combinations of materials can be used. For example, a bottom cell can include a p-n junction formed of a germanium-based polymer, a middle cell can include CsSnI₃, and a top cell can include CsSnCl₂I. As another example, a four junction cell can be implemented with a germanium-based polymer in a bottom cell under the triple junction cell illustrated in FIG. 8. As another example, a two junction cell can be implemented with various pairwise combinations of the cells illustrated in FIG. 8. As another example, the specific halide materials illustrated in FIG. 8 can be substituted with different halide materials of formula (1) or with other materials with bandgap energies in suitable ranges. As another example, one or more of the n-type layers illustrated in FIG. 8 can be composed of wide bandgap oxide materials, such as F-doped TiO₂. As a further example, one or more of the cells illustrated in FIG. 8 can include a p-n junction formed of the same halide material but with different doping type. It is also contemplated that an encapsulation layer can be included for other implementations, such as by depositing an insulator on exposed surfaces of the stacked cells, as an alternative to, or in combination with, the use of a sealing structure.

### EXAMPLES

The following examples describe specific aspects of some embodiments of the disclosure to illustrate and provide a description for those of ordinary skill in the art. The examples should not be construed as limiting the disclosure, as the examples merely provide specific methodology useful in understanding and practicing some embodiments of the disclosure.

### Example 1

### Characterization of Halide Materials

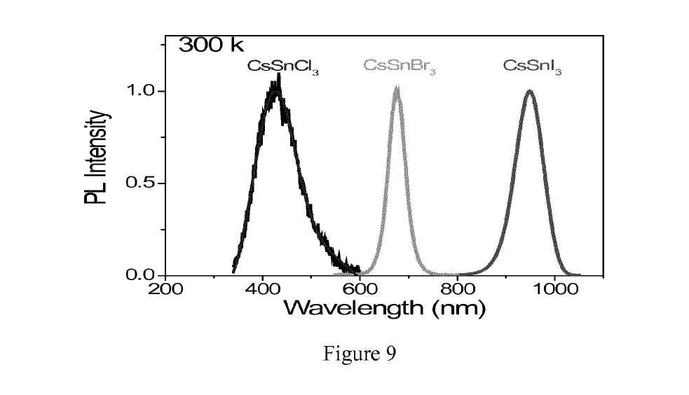

FIG. 9 illustrates emission spectra of three direct bandgap halide materials, namely CsSnI₃ (about 1.3 eV), CsSnBr₃ (about 1.7 eV), and CsSnCl₃ (about 2.4 eV). The halide materials exhibit photoluminescence with high intensities. The halide materials are semiconductors, and the photoluminescence emission is used to illustrate the bandgap energies of the materials. The halide materials each absorb (e.g., have high absorption coefficients) from short wavelengths to the band edge.

### Example 2

### Characterization of Halide Materials

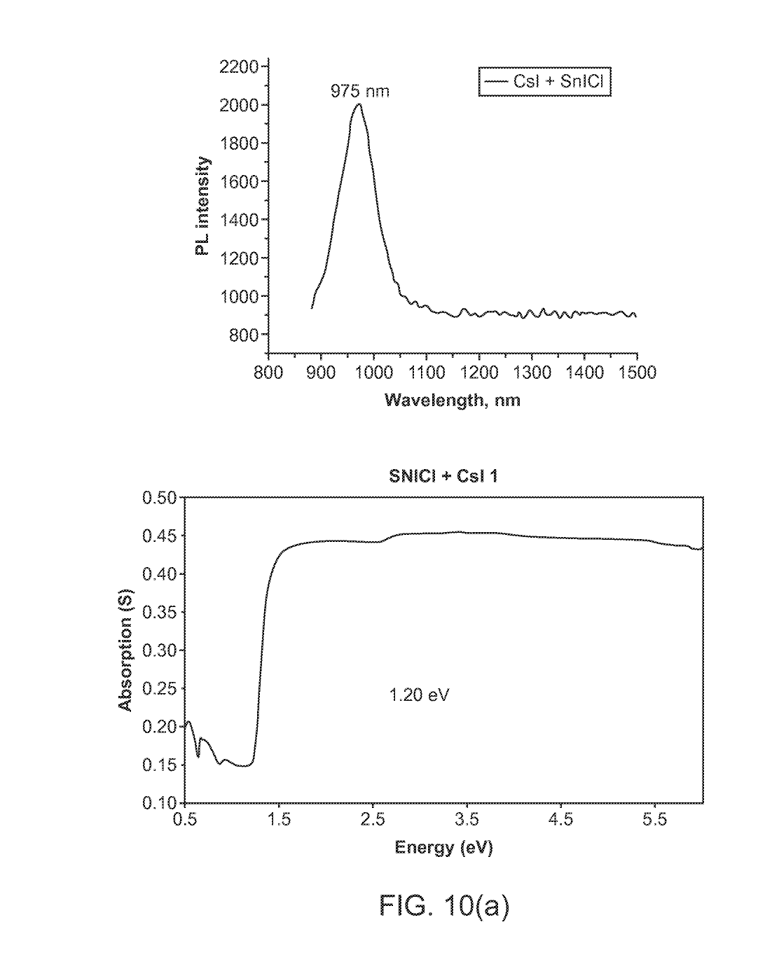

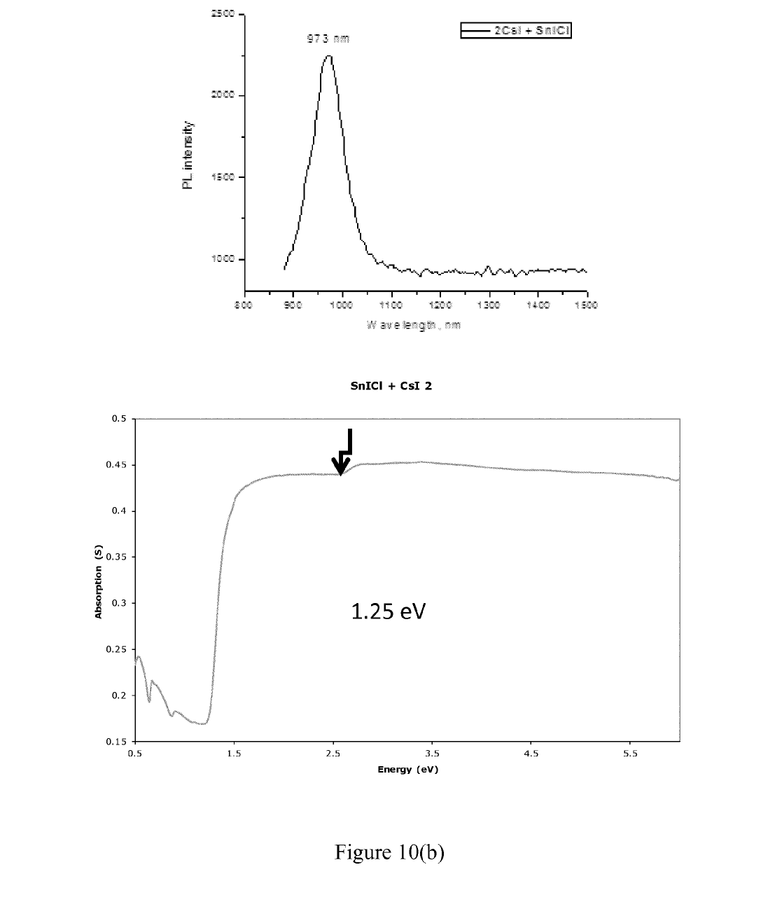

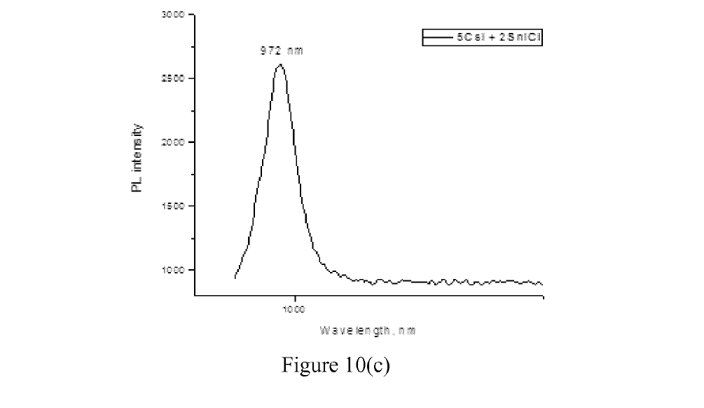

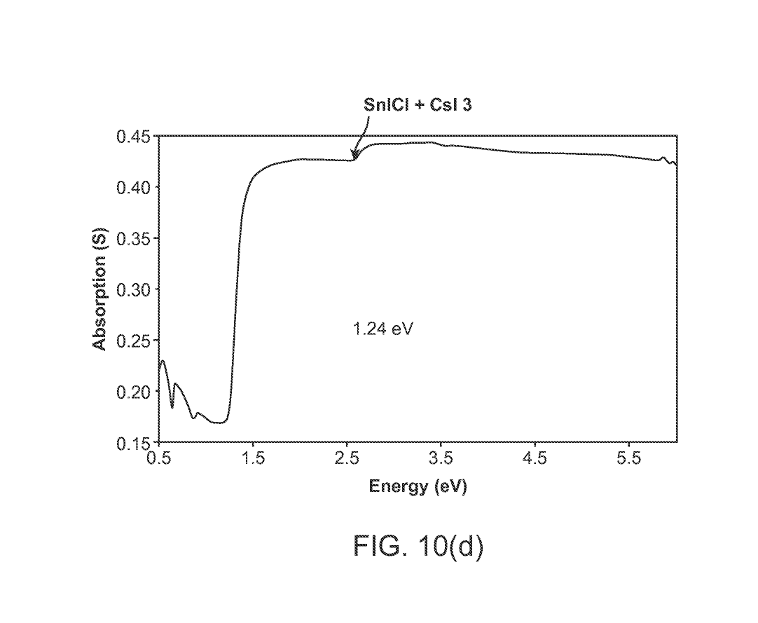

FIGS. 10(a)-(d) illustrate emission and absorption spectra of halide materials formed with varying stoichiometric ratios of reactants. A dominant or primary material has a band edge of about 1.2 eV to about 1.25 eV, and a higher band edge material (about 2.5 eV) is present at a lower concentration.

### Example 3

### Characterization of Halide Materials

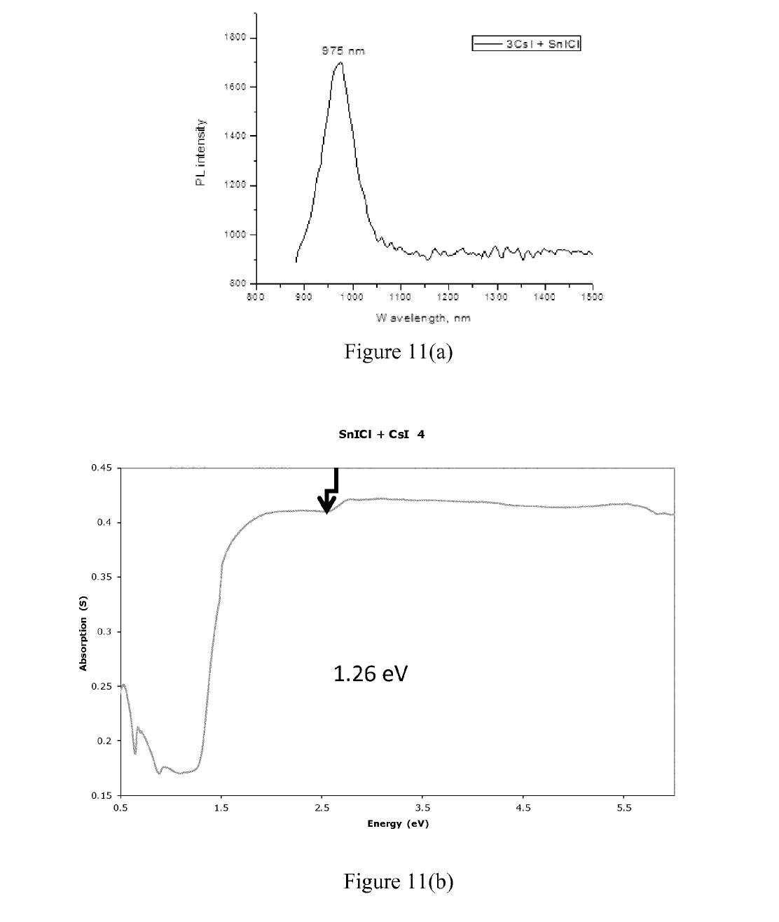

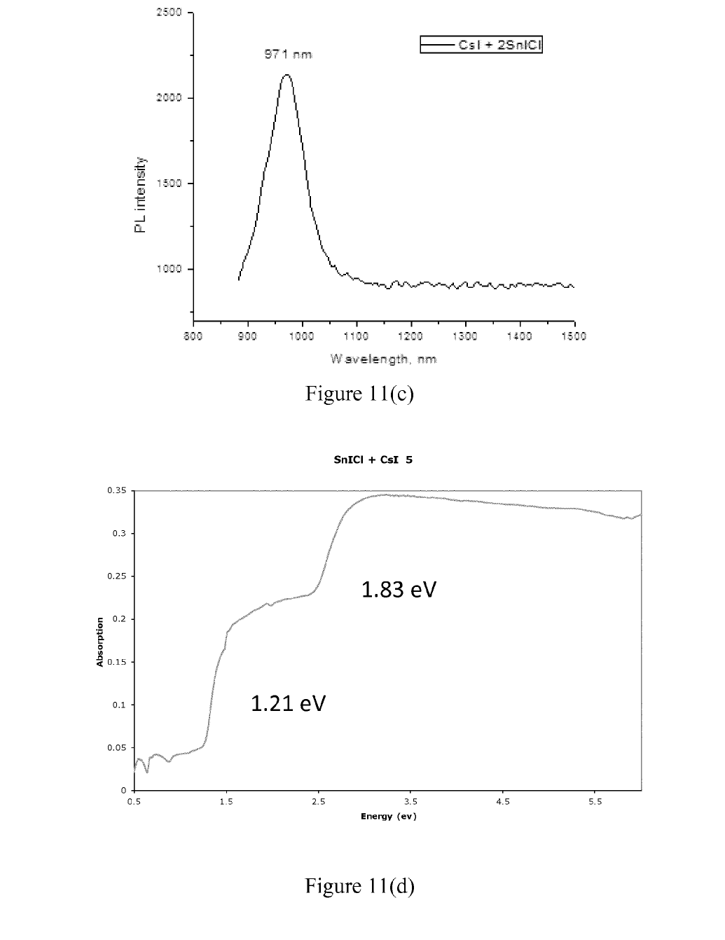

FIGS. 11(a)-(d) illustrate emission and absorption spectra of halide materials formed with varying stoichiometric ratios of reactants. A dominant or primary material has a band edge of about 1.21 eV or about 1.26 eV, and a higher band edge material is present at a lower concentration.

### Example 4

### Characterization of Halide Materials

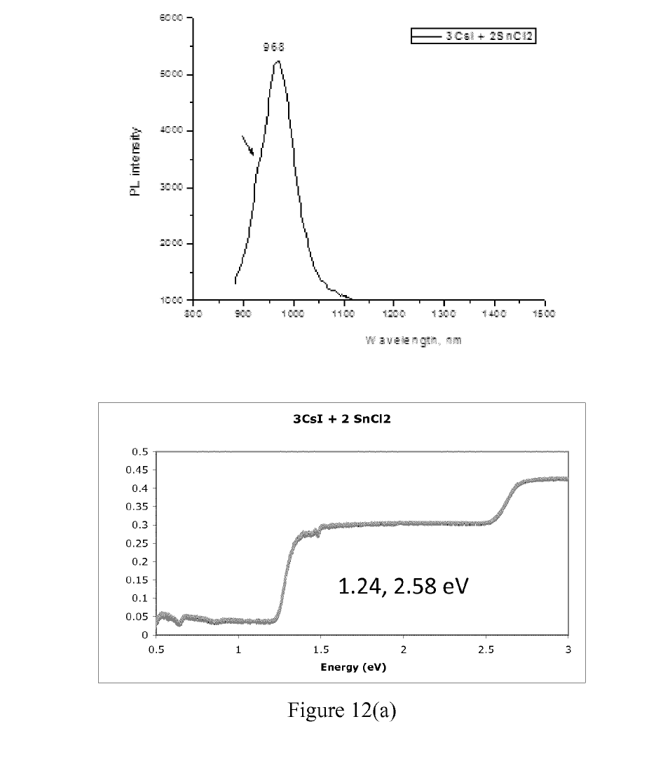

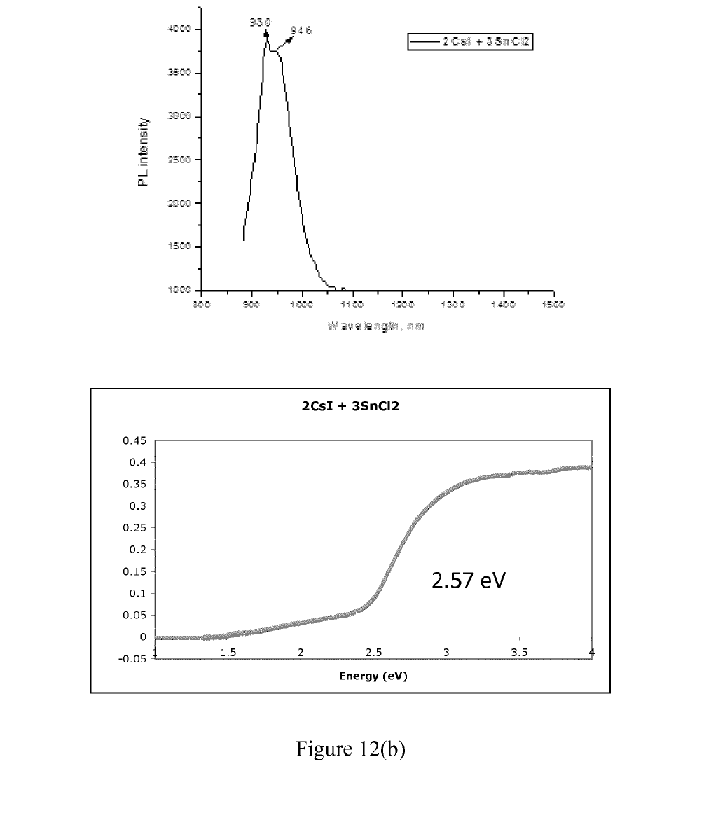

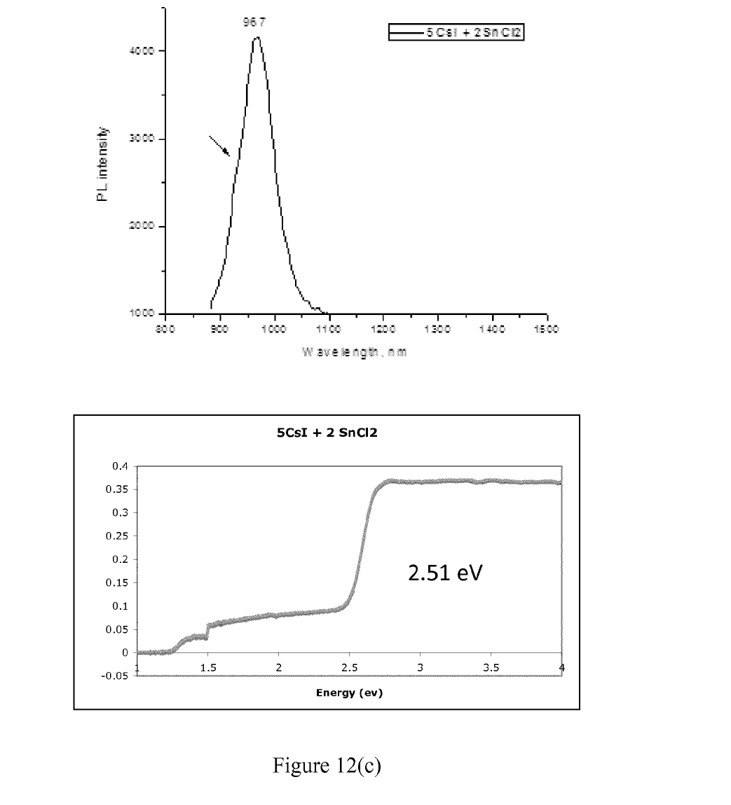

FIGS. 12(a)-(c) illustrate emission and absorption spectra of halide materials formed with varying stoichiometric ratios of reactants (CsI+SnCl₂=3:2, 2:3, 5:2). A dominant or primary material has a band edge of about 1.24 eV, and a higher band edge material is present at a lower concentration. Yellow crystals (about 2.58 eV) were identified as Cs₂SnI₂Cl₂.

### Example 5

### Characterization of Halide Material

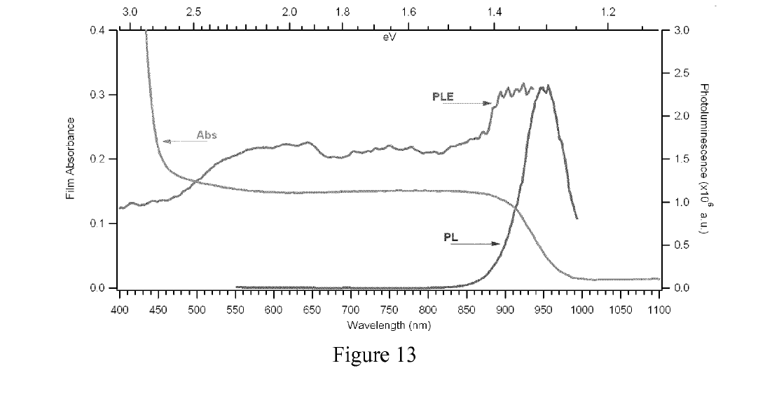

Optical spectra were obtained for a thin film of a halide material. As illustrated in FIG. 13, the halide material exhibits photoluminescence with a peak emission at about 950 nm, undergoes excitation across a broad region of the spectrum (according to its excitation spectrum), and has band edges of about 950 nm and about 450 nm (according to its absorption spectrum). The peak emission varies from about 920 nm to about 980 nm depending on preparation method, and a width of the emission has a FWHM of about 65 nm (little variation with peak emission wavelength). Possibly multiple halide materials may be included in the thin film (e.g., CsSnI₃ plus one or more additional materials).

### Example 6

### Characterization of Halide Material

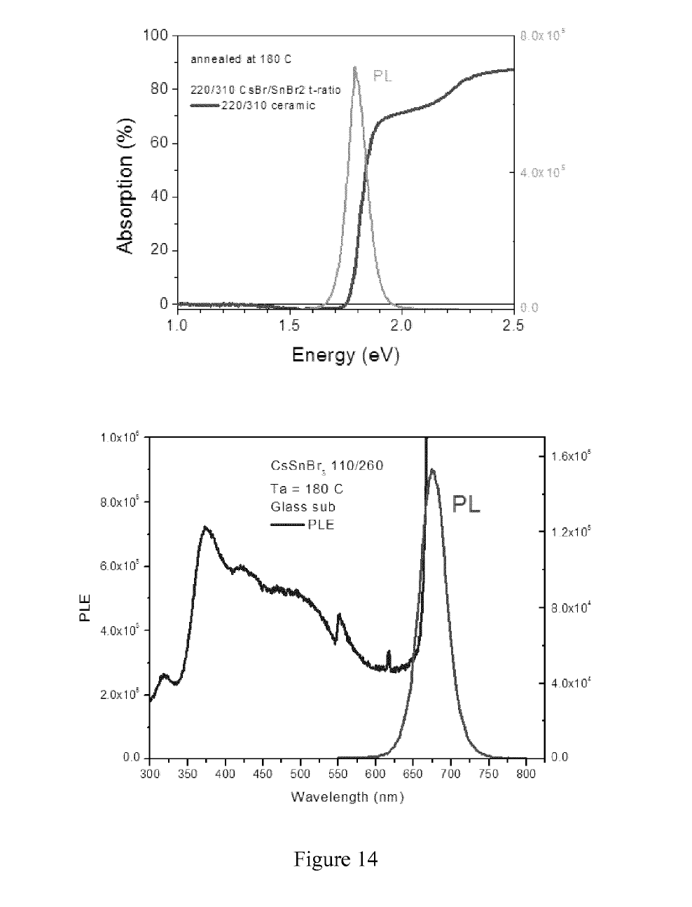

FIG. 14 illustrates emission, excitation, and absorption spectra of a black halide material (CsSnBr₃). A band edge of about 1.75 eV was observed.

### Example 7

### Characterization of Halide Material

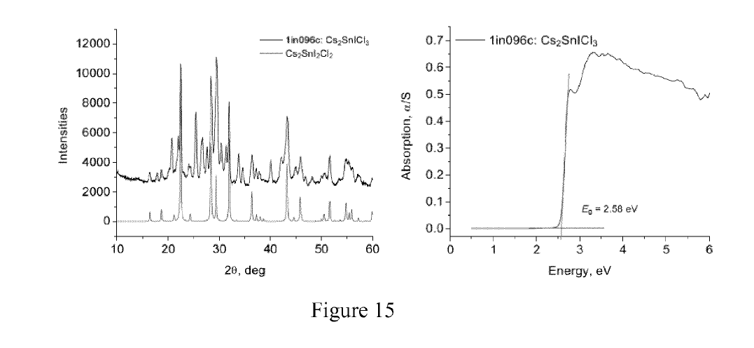

FIG. 15 illustrates X-ray diffraction and absorption spectra of a yellow halide material (Cs₂SnICl₃). A band edge of about 2.58 eV was observed.

### Example 8

### Characterization of Halide Material

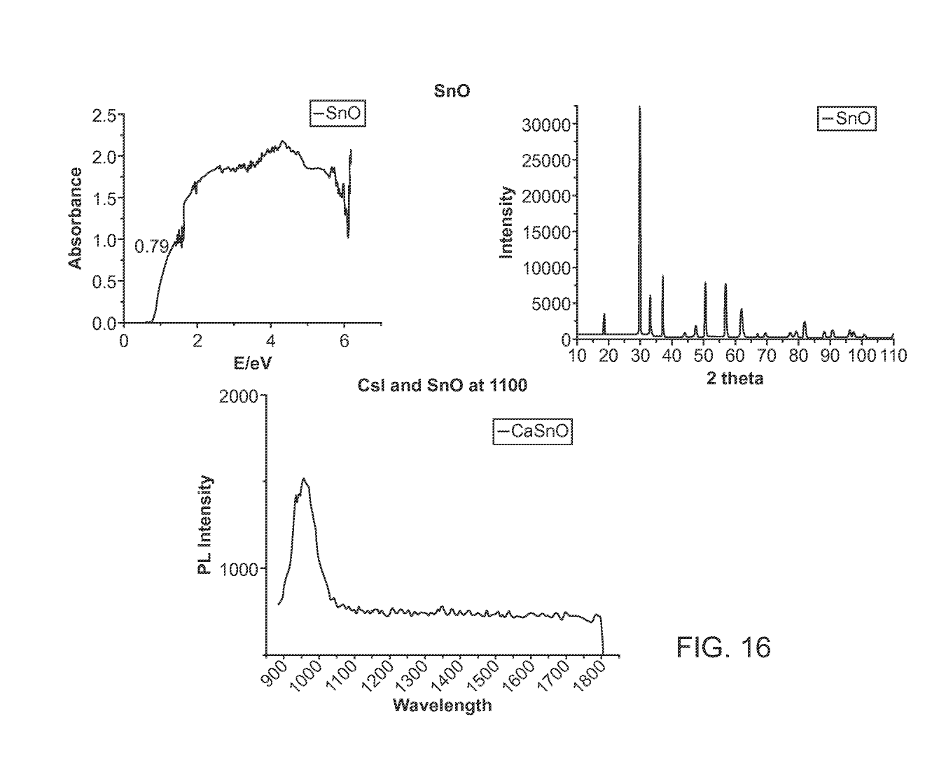

FIG. 16 illustrates X-ray diffraction and absorption spectra of SnO, and an emission spectrum of a halide material formed by reacting SnO and CsI at about 1100° C.

### Example 9

### Characterization of Halide Materials

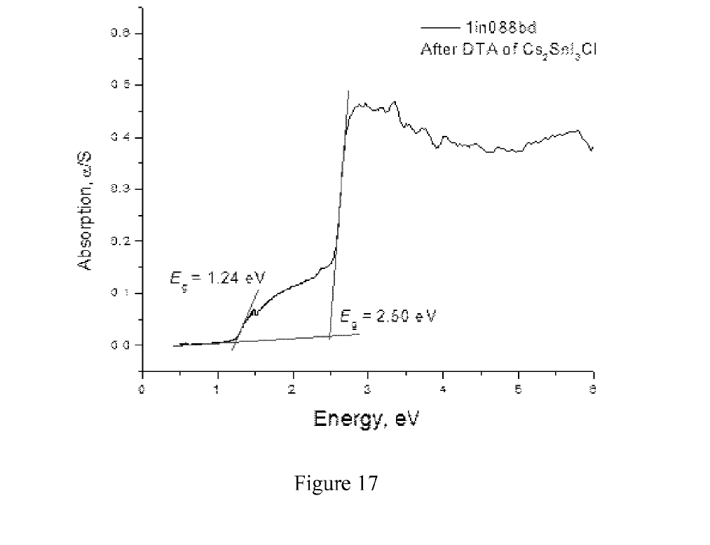

FIG. 17 illustrates absorption spectra of Cs₂SnCl₂I₂ (yellow), CsSnBr₂I (black), Cs₂SnBr₂I₂ (black), and Cs₂SnI₃Cl.

A practitioner of ordinary skill in the art requires no additional explanation in developing the halide materials and PV cells described herein but may nevertheless find some helpful guidance by examining U.S. Pat. No. 7,641,815, U.S. Patent Application Publication No. 2010/0316331, U.S. Patent Application Publication No. 2011/0180757, and U.S. Patent Application Publication No. 2010/0136769, the disclosures of which are incorporated herein by reference in their entirety.

As used herein, the singular terms “a,” “an,” and “the” include plural referents unless the context clearly dictates otherwise. Thus, for example, reference to a halide material can include multiple halide materials unless the context clearly dictates otherwise.

As used herein, the term “set” refers to a collection of one or more elements. Thus, for example, a set of layers can include a single layer or multiple layers. Elements of a set can also be referred to as members of the set. Elements of a set can be the same or different. In some instances, elements of a set can share one or more common characteristics.

As used herein, the terms “optional” and “optionally” mean that the subsequently described event or circumstance may or may not occur, and that the description includes instances where the event or circumstance occurs and instances in which it does not.

As used herein, the terms “about” and “substantially” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±5%, such as less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the term “size” refers to a characteristic dimension of an object. Thus, for example, a size of an object that is spherical can refer to a diameter of the object. In the case of an object that is non-spherical, a size of the non-spherical object can refer to a diameter of a corresponding spherical object, where the corresponding spherical object exhibits or has a particular set of derivable or measurable characteristics that are substantially the same as those of the non-spherical object. Alternatively, or in conjunction, a size of a non-spherical object can refer to an average of various orthogonal dimensions of the object. Thus, for example, a size of an object that is a spheroidal can refer to an average of a major axis and a minor axis of the object. When referring to a set of objects as having a particular size, it is contemplated that the objects can have a distribution of sizes around the particular size. Thus, as used herein, a size of a set of objects can refer to a typical size of a distribution of sizes, such as an average size, a median size, or a peak size.

As used herein, the term “sub-micron range” refers to a general range of dimensions less than about 1 μm or less than about 1,000 nm, such as less than about 999 nm, less than about 900 nm, less than about 800 nm, less than about 700 nm, less than about 600 nm, less than about 500 nm, less than about 400 nm, less than about 300 nm, or less than about 200 nm, and down to about 1 nm or less. In some instances, the term can refer to a particular sub-range within the general range, such as from about 10 nm to just below about 1 μm, from about 1 nm to about 100 nm, from about 100 nm to about 200 nm, from about 200 nm to about 300 nm, from about 300 nm to about 400 nm, from about 400 nm to about 500 nm, from about 500 nm to about 600 nm, from about 600 nm to about 700 nm, from about 700 nm to about 800 nm, from about 800 nm to about 900 nm, or from about 900 nm to about 999 nm.

A set of characteristics of a material can sometimes vary with temperature. Unless otherwise specified herein, a characteristic of a material can be specified at room temperature, such as 300K or 27° C.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, or process to the objective, spirit and scope of the disclosure. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations are not limitations of the disclosure.

What is claimed is:

1. A photovoltaic cell, comprising:
a front contact;
a back contact;
a set of stacked layers between the front contact and the back contact; and
an encapsulation layer covering side surfaces of the set of stacked layers,
wherein at least one of the set of stacked layers includes a halide material having the formula
[AₐB_{b}XₓX′_{x′}X″_{x″}X′″_{x′″}][dopants],
A is selected from elements of Group 1 and organic moieties,
B is selected from elements of Group 14,
X, X′, X″, and X′″ are independently selected from elements of Group 17,
a is in the range of 1 to 12,
b is in the range of 1 to 8, and
a sum of x, x′, x″, and x′″ is in the range of 1 to 12.

2. The photovoltaic cell of claim 1, wherein the halide material is a p-type halide material, and the set of stacked layers includes a hole transporting layer including the p-type halide material.

3. The photovoltaic cell of claim 1, wherein the set of stacked layers includes a photoactive layer including the halide material.

4. The photovoltaic cell of claim 1, wherein the halide material is a p-type halide material, and the set of stacked layers includes a p-type absorber layer including the p-type halide material.

5. The photovoltaic cell of claim 1, wherein the halide material is an n-type halide material, and the set of stacked layers includes an n-type emitter layer including the n-type halide material.

6. The photovoltaic cell of claim 1, wherein A is cesium, and B is tin.

7. The photovoltaic cell of claim 6, wherein a is in the range of 1 to 4, b is in the range of 1 to 2, and the sum of x, x′, x″, and x′″ is in the range of 3 to 6.

8. The photovoltaic cell of claim 1, wherein the encapsulation layer includes an insulator.

9. A photovoltaic cell, comprising:
a top substrate;
a bottom substrate;
a set of stacked layers between the top substrate and the bottom substrate; and
a sealing structure extending between the top substrate and the bottom substrate and surrounding side surfaces of the set of stacked layers,
wherein at least one of the set of stacked layers includes a halide material having the formula
[AₐB_{b}XₓX′ₓX″_{x″}X′″_{x′″}][dopants],
A is selected from elements of Group 1 and organic moieties,
B is selected from elements of Group 14,
X, X′, X″, and X′″ are independently selected from elements of Group 17,
a is in the range of 1 to 12,
b is in the range of 1 to 8, and
a sum of x, x′, x″, and x′″ is in the range of 1 to 12.

10. The photovoltaic cell of claim 9, wherein the halide material is a p-type halide material.

11. The photovoltaic cell of claim 9, wherein the halide material is an n-type halide material.

12. The photovoltaic cell of claim 9, wherein the halide material is a first halide material that is p-type, one of the set of stacked layers is a p-type absorber layer including the first halide material, another one of the set of stacked layers is an n-type emitter layer, and the p-type absorber layer and the n-type emitter layer form a p-n junction.

13. The photovoltaic cell of claim 12, wherein the n-type emitter layer includes a second halide material that is n-type.

14. A photovoltaic cell, comprising:
a top conductive layer;
a bottom conductive layer; and
a set of stacked layers between the top conductive layer and the bottom conductive layer and including a pair of photoactive layers,
wherein the top conductive layer covers a top surface and side surfaces of the set of stacked layers,
wherein at least one of the pair of photoactive layers includes a halide material having the formula
[AₐB_{b}XₓX′_{x′}X″_{x″}X′″_{x′″}][dopants],
A is selected from elements of Group 1 and organic moieties,
B is selected from elements of Group 14,
X, X′, X″, and X′″ are independently selected from elements of Group 17,
a is in the range of 1 to 12,
b is in the range of 1 to 8, and
a sum of x, x′, x″, and x′″ is in the range of 1 to 12.

15. The photovoltaic cell of claim 14, further comprising a spacer layer disposed on the bottom conductive layer and surrounding a periphery of the set of stacked layers, and the top conductive layer is electrically isolated from the bottom conductive layer by the spacer layer.

16. The photovoltaic cell of claim 14, wherein the halide material is a p-type halide material, and the pair of photoactive layers includes a p-type absorber layer including the p-type halide material.

17. The photovoltaic cell of claim 14, wherein the halide material is an n-type halide material, and the pair of photoactive layers includes an n-type emitter layer including the n-type halide material.

18. The photovoltaic cell of claim 14, wherein a is 1, and the sum of x, x′, x″, and x′″ is 1+2b.

19. The photovoltaic cell of claim 14, wherein a is 1, and the sum of x, x′, x″, and x′″ is 2+2b.

20. A photovoltaic cell, comprising:
a top conductive layer;
a bottom conductive layer; and
a set of stacked layers between the top conductive layer and the bottom conductive layer and including a top photoactive layer and a bottom photoactive layer,
wherein the top photoactive layer covers a top surface and side surfaces of the bottom photoactive layer,
wherein the bottom photoactive layer includes a halide material having the formula
[AₐB_{b}XₓX′ₓX″_{x″}X′″_{x′″}][dopants],
A is selected from elements of Group 1 and organic moieties,
B is selected from elements of Group 14,
X, X′, X″, and X′″ are independently selected from elements of Group 17,
a is in the range of 1 to 12,
b is in the range of 1 to 8, and
a sum of x, x′, x″, and x′″ is in the range of 1 to 12.

21. The photovoltaic cell of claim 20, wherein the halide material is a p-type halide material, and the bottom photoactive layer is a p-type absorber layer including the p-type halide material.

22. The photovoltaic cell of claim 21, wherein the top photoactive layer is an n-type emitter layer including a semiconductor material selected from semiconductor oxides, amorphous silicon, microcrystalline silicon, CdS, CdSe, and ZnS.

23. The photovoltaic cell of claim 21, wherein A is cesium, B is tin, a is in the range of 1 to 4, b is in the range of 1 to 2, and the sum of x, x′, x″, and x′″ is in the range of 3 to 6.

24. A multijunction photovoltaic cell, comprising:
a front contact;
a back contact; and
a set of stacked layers between the front contact and the back contact and including:
a first pair of photoactive layers corresponding to a first cell having a first bandgap energy; and
a second pair of photoactive layers corresponding to a second cell that is disposed between the first cell and the back contact and having a second bandgap energy that is smaller than the first bandgap energy,
wherein at least one of the set of stacked layers includes a halide material having the formula
[AₐB_{b}XₓX′ₓX″_{x″}X′″_{x′″}][dopants],
A is selected from elements of Group 1 and organic moieties,
B is selected from elements of Group 14,
X, X′, X″, and X′″ are independently selected from elements of Group 17,
a is in the range of 1 to 12,
b is in the range of 1 to 8, and
a sum of x, x′, x″, and x′″ is in the range of 1 to 12.

25. The multijunction photovoltaic cell of claim 24, wherein the halide material is a p-type halide material, and the first pair of photoactive layers includes a p-type absorber layer including the p-type halide material and having the first bandgap energy.

26. The multijunction photovoltaic cell of claim 24, wherein the halide material is a p-type halide material, and the second pair of photoactive layers includes a p-type absorber layer including the p-type halide material and having the second bandgap energy.

27. The multijunction photovoltaic cell of claim 24, wherein A is cesium, B is tin, a is in the range of 1 to 4, b is in the range of 1 to 2, and the sum of x, x′, x″, and x′″ is in the range of 3 to 6.

28. The multijunction photovoltaic cell of claim 24, wherein the halide material is selected from p-type CsSnI₃, p-type CsSnCl₂Br, and p-type CsSnCl₃.
